(19) United States
(12) Patent Application Publication
(10) Pub. No.: US 2009/0001450 A1
(43) Pub. Date: Jan. 1, 2009

(54) Non-volatile memory device and method of fabricating the same

(75) Inventors: Ju-Ri Kim, Hwaseong-si (KR); Jae-Hwang Kim, Yongin-si (KR); Sung-Chul Park, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/213,854

(22) Filed: Jun. 25, 2008

(30) Foreign Application Priority Data
Jun. 26, 2007 (KR) 10-2007-0063057

(51) Int. Cl. H01L 29/792; H01L 21/336

(52) U.S. Cl. 257/324; 438/157; 257/E21.411; 257/E29.309

(57) ABSTRACT

Provided are a non-volatile memory device and a method of fabricating the same. The non-volatile memory device may include a lower semiconductor substrate, an upper semiconductor pattern on the lower semiconductor substrate, a device isolation pattern defining an active region in the lower semiconductor substrate and the upper semiconductor pattern, a lower charge storage layer between the upper semiconductor pattern and the lower semiconductor substrate, a gate conductive structure crossing over the upper semiconductor pattern, a first upper charge storage layer and a second upper charge storage layer spaced apart from each other between the gate conductive structure and the upper semiconductor pattern, and a source/drain region in the upper semiconductor pattern on both sides of the gate conductive structure.

### PRIORITY STATEMENT

This U.S. non-provisional patent application claims priority under 35 U.S.C. §119 to Korean Patent Application No. 10-2007-0063057, filed on Jun. 26, 2007, in the Korean Intellectual Property Office (KIPO), the entire contents of which are hereby incorporated by reference.

### BACKGROUND

1. Field

Example embodiments relate to a semiconductor device and a method of fabricating the same. Other example embodiments relate to a non-volatile memory device and a method of fabricating the same.

2. Description of the Related Art

Semiconductor memory devices generally may be classified into a volatile memory device and a non-volatile memory device. The volatile memory device may have relatively fast data input/output but may lose stored data when no power is applied, e.g., dynamic random access memory (DRAM) and a static random access memory (SRAM).

A flash memory device may be a non-volatile memory device that is highly integrated and has the merits of an erasable programmable read only memory (EPROM) with an electrically erasable programmable read only memory (EEPROM). The flash memory device may be classified into a floating gate type flash memory device and a floating trap type flash memory device according to the type of a data storage layer constituting a unit cell.

Unlike the floating gate type flash memory device which stores charges on a polysilicon layer, the floating trap type flash memory device stores charges on the trap of a non-conductive charge trap layer. A memory cell of the floating trap type flash memory device may have a gate with a stack structure. The gate may include a tunnel oxide layer, a silicon nitride layer (e.g., a charge trap layer), a blocking oxide layer, and a conductive layer, which may be sequentially stacked on a silicon substrate.

A memory cell of the floating trap type memory device may have a single bit structure in order to represent one of logic 0 and logic 1, based on whether there are charges trapped in the silicon nitride layer, e.g., the charge trap layer, or not.

### SUMMARY

Example embodiments provide a non-volatile memory device including a multi bit structure and a method of fabricating the same.

According to example embodiments, a non-volatile memory device may include a lower semiconductor substrate, an upper semiconductor pattern on the lower semiconductor substrate, a device isolation pattern defining an active region in the lower semiconductor substrate and the upper semiconductor pattern, a lower charge storage layer interposed between the upper semiconductor pattern and the lower semiconductor substrate, a gate conductive structure crossing over the upper semiconductor pattern, a first upper charge storage layer and a second upper charge storage layer spaced apart from each other between the gate conductive structure and the upper semiconductor pattern, and a source/drain region formed in the upper semiconductor pattern on both sides of the gate conductive structure.

In example embodiments, the gate conductive structure may include a gate conductive pattern on the first and second upper charge storage layers and the upper semiconductor pattern between the spaced apart first and second upper charge storage layers, and the non-volatile memory devices may further include a gate insulation layer formed between the first and second upper charge storage layers and between the gate conductive pattern and the upper semiconductor pattern.

In example embodiments, each of the first and second upper charge storage layers may include an upper tunnel insulation pattern on the upper semiconductor pattern, an upper charge trap pattern on the upper tunnel insulation pattern, and an upper blocking insulation pattern on the upper charge trap pattern. In example embodiments, the gate conductive structure may include a first gate conductive pattern between the first upper charge storage layer and the second upper charge storage layer, a second gate conductive pattern adjacent to a first sidewall of the first gate conductive pattern, and a third gate conductive pattern adjacent to a second sidewall of the first gate conductive pattern facing the first sidewall, and the non-volatile memory devices may further include a gate insulation layer between the upper semiconductor pattern and the first gate conductive pattern, between the first sidewall and the second conductive pattern, and between the second sidewall and the third gate conductive pattern.

In example embodiments, the first upper charge storage layer may be between the second gate conductive pattern and the upper semiconductor pattern, and the second upper charge storage layer may be between the third gate conductive pattern and the upper semiconductor pattern.

In example embodiments, each of the first and second upper charge storage layers may include an upper tunnel insulation patter on the upper semiconductor pattern, an upper charge trap pattern on the upper tunnel insulation pattern, and an upper blocking insulation pattern on the upper charge trap pattern.

In example embodiments, the gate conductive structure may further include a connection part to electrically connect the first, second, and third gate conductive patterns, the connection part being formed on an upper portion of the first gate conductive pattern, an upper portion of the second gate conductive pattern, and an upper portion of the third gate conductive pattern. In example embodiments, the connection part may include a metalized material.

In example embodiments, the lower charge storage layer may include a lower blocking layer on the lower semiconductor substrate, a lower tunnel insulation layer contacting the upper semiconductor pattern on the lower blocking layer, and a lower charge trap layer between the lower blocking layer and the lower tunnel insulation layer.

In example embodiments, the non-volatile memory devices may further include a lower high concentration impurity region formed in an upper portion of the lower semiconductor substrate, and a lower gate contact spaced apart from the gate conductive structure and electrically connected to the lower high concentration impurity region through the upper semiconductor pattern and the lower charge storage layer, wherein the upper semiconductor pattern and the lower charge storage layer may include a lower gate groove to expose the lower high concentration impurity region.

In example embodiments, the non-volatile memory devices may further include a first spacer on both sidewalls of the gate conductive structure and a second spacer at an inner wall of the lower gate groove.

According to example embodiments, methods of fabricating a non-volatile memory device may include providing a lower semiconductor substrate, forming an upper semiconductor pattern on the lower semiconductor substrate, forming a device isolation pattern to define an active region in the lower semiconductor substrate and the upper semiconductor pattern, forming a lower charge storage layer between the upper semiconductor pattern and the lower semiconductor substrate, forming a gate conductive structure to cross over the upper semiconductor pattern, forming a first upper charge storage layer and a second upper charge storage layer spaced apart from each other between the gate conductive structure and the upper semiconductor pattern, and forming a source/drain region in the upper semiconductor pattern on both sides of the gate conductive structure.

In example embodiments, forming the upper semiconductor pattern may include forming a sacrificial layer on a preliminary lower semiconductor substrate, and forming an upper semiconductor layer on the sacrificial layer.

In example embodiments, the sacrificial layer may have an etch selectivity with respect to the upper semiconductor layer and the preliminary lower semiconductor substrate. In example embodiments, the sacrificial layer may include a silicon germanium layer formed by performing an epitaxial growth process. In example embodiments, the upper semiconductor layer may include a silicon layer formed by performing an epitaxial growth process.

In example embodiments, forming the device isolation pattern may include patterning the upper semiconductor layer, the sacrificial layer, and the preliminary lower semiconductor substrate to form an upper semiconductor pattern, a sacrificial pattern, and a lower semiconductor substrate, which may have a device isolation trench, and forming a device isolation insulation layer to fill the device isolation trench. In example embodiments, the device isolation insulation layer may have an etch selectivity with respect to the upper semiconductor layer and the sacrificial layer.

In example embodiments, forming the lower charge storage layer may include removing the sacrificial pattern to expose a bottom surface of the upper semiconductor pattern and a top surface of the lower semiconductor substrate, forming a lower tunnel insulation layer on the bottom surface of the upper semiconductor pattern and a lower blocking layer on the top surface of the lower semiconductor substrate, and forming a lower charge trap layer between the lower tunnel insulation layer and the lower blocking layer.

In example embodiments, removing the sacrificial pattern may include partially exposing the device isolation insulation layer contacting the upper semiconductor pattern, recessing the exposed device isolation insulation layer to expose a side of the sacrificial pattern, and selectively performing an isotropic etching process on the exposed sacrificial pattern.

In example embodiments, partially exposing the device isolation insulation layer may include forming a first mask layer on the upper semiconductor pattern and the device isolation insulation layer, and patterning the first mask layer to form a first mask pattern having a first groove, the first groove exposing the upper semiconductor pattern and the device isolation insulation layer that contacts the upper semiconductor pattern.

In example embodiments, the first mask layer may have an etch selectivity with respect to the upper semiconductor pattern, the sacrificial pattern, and the device isolation insulation layer. In example embodiments, recessing the exposed device isolation insulation layer may include etching the device isolation insulation layer, exposed through the first groove, to form a second groove, the second groove extending from the first groove partially.

In example embodiments, forming the lower tunnel insulation layer and the lower blocking layer may include forming a silicon oxide layer by performing a chemical vapor deposition (CVD) process. In example embodiments, forming the lower charge trap layer may include forming a silicon nitride layer by performing a CVD process.

In example embodiments, forming the first and second upper charge storage layers may include forming an upper tunnel insulation layer on the upper semiconductor pattern, an upper charge trap layer on the upper tunnel insulation layer, and an upper blocking layer on the upper charge trap layer, and patterning the upper blocking layer, the upper charge trap layer, and the upper tunnel insulation layer to form a preliminary first upper charge storage layer and a preliminary second upper charge storage layer, which may be spaced apart from each other, wherein each of the preliminary first and second upper charge storage layers may include a preliminary upper blocking pattern, a preliminary upper charge trap pattern, and a preliminary upper tunnel insulation pattern.

In example embodiments, forming the gate insulation layer and the gate conductive structure may include forming a gate insulation layer on the exposed upper semiconductor layer, and forming a gate conductive layer to cover the gate insulation layer, the preliminary first upper charge storage layer, and the preliminary second upper charge storage layer.

In example embodiments, forming the first and second upper charge storage layers may include forming an upper tunnel insulation layer on the upper semiconductor pattern, an upper charge trap layer on the upper tunnel insulation layer, and an upper blocking layer on the upper charge trap layer, forming a second mask pattern on the upper blocking layer, and etching the upper blocking layer, the upper charge trap layer, and the upper tunnel insulation layer by using the second mask pattern as an etch mask to form a trench and preliminary first and second upper charge storage layers, the trench exposing the upper semiconductor pattern and being between the preliminary first and second upper charge storage layers, the preliminary first and second upper charge storage layers being spaced apart from each other, wherein each of the preliminary first and second upper charge storage layers may include a preliminary upper blocking pattern, a preliminary upper charge trap pattern, and a preliminary upper tunnel insulation pattern.

In example embodiments, forming the gate insulation layer and the gate conductive structure may include forming a gate insulation layer on the exposed upper semiconductor substrate and on an inner wall of the trench, forming a first gate conductive layer to fill the trench having the gate insulation layer in order to form a first gate conductive pattern, removing the second mask pattern to expose the preliminary upper blocking pattern, conformally forming a second gate conductive layer on the upper semiconductor pattern including the exposed preliminary upper blocking pattern, and performing an anisotropic etching process on the second gate conductive layer until the first gate conductive pattern may be exposed, in order to form a second gate conductive pattern and a third gate conductive pattern.

In example embodiments, the second mask pattern may have an etch selectivity with respect to the gate insulation layer and the blocking layer. In example embodiments, forming the first and second upper charge storage layers may include performing an anisotropic etching process on the preliminary first and second upper charge storage layers by using the first, second, and third gate conductive patterns as an etch mask until the upper semiconductor pattern may be exposed.

In example embodiments, forming the gate conductive structure may further include forming a first spacer at an outer sidewall of the second gate conductive pattern and an outer sidewall of the third gate conductive pattern, recessing the gate insulation layer, and forming a connection part on an upper portion of the first gate conductive pattern, an upper portion of the second gate conductive pattern, and an upper portion of the third gate conductive pattern. In example embodiments, the connection part may include a metalized material.

In example embodiments, the methods may further include forming a lower high concentration impurity region on an upper portion of the lower semiconductor substrate, forming a lower gate groove spaced apart from the gate conductive structure and exposing the lower high concentration impurity region through the upper semiconductor pattern and the lower charge storage layer, forming an interlayer insulation layer to cover the exposed lower high concentration impurity region, and forming a lower gate contact to be electrically connected to the lower high concentration impurity region through the interlayer insulation layer. In example embodiments, forming a second spacer on an inner wall of the lower gate groove.

### BRIEF DESCRIPTION OF THE FIGURES

Example embodiments will be more clearly understood from the following detailed description taken in conjunction with the accompanying drawings. FIGS. 1-21C represent non-limiting, example embodiments as described herein.

FIG. 1 is a non-volatile memory device according to example embodiments;

FIGS. 2A through 10A are plan views illustrating a method of fabricating a non-volatile memory device according to example embodiments;

FIGS. 2B through 10B and 2C through 10C are sectional views taken along a dotted line X-X′ and a dotted line Y-Y′ of FIGS. 2A through 10A, respectively;

FIG. 11 is a non-volatile memory device according to example embodiments;

FIGS. 12A through 21A are plan views illustrating a method of fabricating a non-volatile memory device according to example embodiments; and

FIGS. 12B through 21B and 12C through 21C are sectional views taken along a dotted line X-X′ and a dotted line Y-Y′ of FIGS. 12A through 21 A, respectively.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will be described below in more detail with reference to the accompanying drawings. Example embodiments may, however, be embodied in different forms and should not be construed as limited to the embodiments set forth herein. Rather, these embodiments may be provided so that this disclosure will be thorough and complete, and will fully convey the scope of example embodiments to those skilled in the art. In the figures, the dimensions of layers and regions may be exaggerated for clarity of illustration. It will also be understood that when a layer (or film) may be referred to as being ‘on’ another layer or substrate, it can be directly on the other layer or substrate, or intervening layers may also be present. Further, it will be understood that when a layer may be referred to as being ‘under’ another layer, it can be directly under, and one or more intervening layers may also be present. In addition, it will also be understood that when a layer may be referred to as being ‘between’ two layers, it can be the only layer between the two layers, or one or more intervening layers may also be present. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

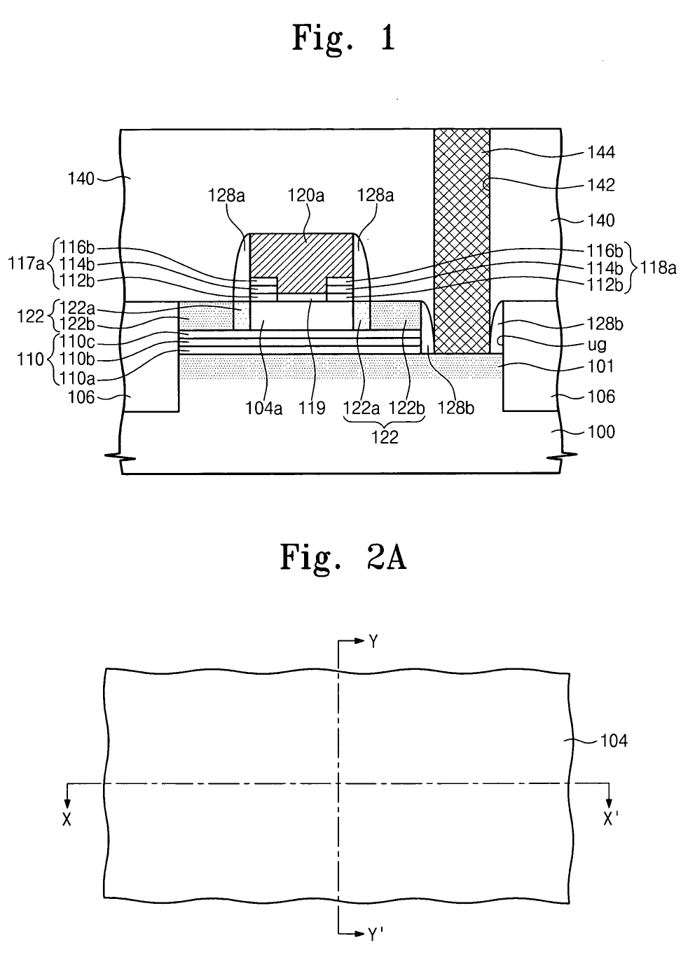

FIG. 1 is a non-volatile memory device according to example embodiments. A lower semiconductor substrate 100 may be provided. The lower semiconductor substrate 100 may be a silicon substrate including a P-type impurity. An upper semiconductor pattern 104a may be disposed on the lower semiconductor substrate 100. The upper semiconductor pattern 104a may be a single crystal silicon pattern. A lower high concentration impurity region 101 may be disposed in an upper portion of the lower semiconductor substrate 100. The impurity may be an N-type impurity. The lower high concentration impurity region 101 may be formed with a first depth along an upper surface of the lower semiconductor substrate 100.

A lower charge storage layer 110 may be interposed between the upper semiconductor pattern 104a and the lower semiconductor substrate 100. The lower charge storage layer 110 may include a lower blocking layer 110a on the lower semiconductor substrate 100, a lower tunnel insulation layer 110c contacting the upper semiconductor pattern 104a on the lower blocking layer 110a, and a lower charge trap layer 110b between the lower blocking layer 110a and the lower tunnel insulation layer 110c. For example, the lower tunnel insulation layer 110c may include a silicon oxide layer, a silicon oxide nitride layer, or a higher-k dielectric than the silicon oxide layer. The lower blocking layer 110a may include at least one of the higher-k materials than the silicon oxide layer. For example, the lower blocking layer 110a may include a multilayer having at least one of high-k dielectrics, e.g., an aluminum oxide layer, a hafnium oxide layer, a hafnium aluminum oxide layer, and a zirconium oxide layer. The lower blocking layer 110a may be a silicon oxide layer. The silicon oxide layer may be a medium temperature oxide (MTO) layer. For example, the lower charge trap layer 110b may include at least one of oxide layers of silicon, metal, and silicide and nitride layers of silicon, metal, and silicide. The lower charge trap layer 110b may further include conductive polysilicon dots that may be two-dimensionally arranged on the lower tunnel insulation layer 110c.

The lower semiconductor substrate 100 and the device isolation pattern 106 on the upper semiconductor pattern 104a define an active region. The active region may be the upper semiconductor pattern 104a. A gate conductive structure 120a crosses over the upper semiconductor pattern 104a. The gate conductive structure 120a may be formed of at least one of a metal layer, a metal nitride layer, a metal silicide layer, and a polycrystalline silicon layer. For example, the gate conductive structure 120a may include one of a tantalum nitride layer (TaN), a titanium nitride layer (TiN), a tungsten nitride layer (WN), and a polysilicon layer. The gate conductive structure 120a may be a gate conductive pattern formed of polysilicon. A first spacer 128a may be prepared on both sidewalls of the gate conductive structure 120a. The first spacer 128a may include a silicon nitride layer or a silicon oxide nitride layer (SiON).

A first upper charge storage layer 117a and a second upper charge storage layer 118a may be spaced apart from each other between the gate conductive structure 120a and the upper semiconductor pattern 104a. The first and second upper charge storage layers 117a and 118a may be aligned on both sidewalls of the gate conductive structure 120a. The first and second upper charge storage layers 117a and 118a may include an upper tunnel insulation pattern 112b on the upper semiconductor pattern 104a, an upper charge trap pattern 114b on the upper tunnel insulation pattern 112b, and an upper blocking insulation pattern 116b on the upper charge trap pattern 114b. For example, the upper tunnel insulation patter 112b may include a silicon oxide layer, a silicon oxide nitride layer, or a higher-k dielectric than the silicon oxide layer. The upper blocking insulation pattern 116b may be formed of higher-k materials than the silicon oxide layer. For example, the upper blocking insulation pattern 116b may include a multilayer having at least one high-k dielectrics, e.g., an aluminum oxide layer, a hafnium oxide layer, a hafnium aluminum oxide layer, and a zirconium oxide layer. For example, the upper charge trap pattern 114b may include at least one of oxide layers of silicon, metal, and metal silicide and nitride layers of silicon, metal and metal silicide. The upper charge trap pattern 114b may further include conductive polysilicon dots that are two-dimensionally arranged on the tunnel insulation layer 110c. For example, the upper blocking insulation pattern 116b may include at least one of high-k dielectrics, e.g., an aluminum oxide layer, a hafnium oxide layer, a hafnium aluminum oxide layer, and a zirconium oxide layer.

The gate conductive structure 120a may be disposed on the first and second upper charge storage layers 117a and 118a and on the upper semiconductor pattern 104a between the spaced apart first and second upper charge storage layers 117a and 118a. The gate insulation layer 119 may be interposed between the first and second upper charge storage layers 117a and 118a and between the gate conductive structure 120a and the upper semiconductor pattern 104a. Source/drain regions 122 may be formed on the upper semiconductor pattern 104a on both sides of the gate conductive structure 120a. Each of the source/drain regions 122 may include a low concentration impurity region 122a and a high concentration impurity region 122b. The impurity may be an N-type.

A lower gate groove (ug) may be spaced apart from the gate conductive structure 120a and may be disposed adjacent to the lower high concentration region 101. The lower gate groove (ug) may expose the lower high concentration impurity region 101. A second spacer 128b may be formed on an inner wall of the lower gate groove (ug). The second spacer 128b may include a silicon nitride layer or a silicon oxide nitride layer SiON. An interlayer insulation layer 140 may cover the gate conductive structure 120a and the exposed lower high concentration impurity region 101. A lower gate contact hole 142 may penetrate through the interlayer insulation layer 140 to expose the lower high concentration impurity region 101. A lower gate contact 144 may fill the lower gate contact hole 142 and may be electrically connected to the lower high concentration impurity region 101. The second spacer 128b may prevent or reduce electrical contact between the source/drain region 122 and the lower gate contact 142. Contacts (not shown) may penetrate through the interlayer insulation layer 140 to be electrically connected to the gate conductive structure 120a and the source/drain region 122.

According to example embodiments, a one cell-4 bit non-volatile memory device may be realized by including the first and second upper charge storage layers 117a and 118a and the lower charge storage layer 110 below the first and second upper charge storage layers 117a and 118a. On the other hand, if the charge trap layer is not separated, charges may be locally implanted on a charge trap layer adjacent to the source/drain region in order to be used for a non-volatile memory device of a multi bit structure. However, in the case of a memory device of a short channel, overlap phenomena may occur during charge implantation, and disturb phenomena may occur due to lateral diffusion of implanted charge.

According to example embodiments, because the first and second upper charge storage layers 117a and 118a may be spaced apart from each other, overlap phenomena and disturb phenomena may be suppressed. According to example embodiments, an upper portion of the lower semiconductor substrate 100 may be used as a gate electrode by means of the lower high concentration impurity region 101. For example, a voltage may be independently applied to the upper portion of the lower semiconductor substrate 100. Accordingly, charges may be implanted on or discharged from the lower charge trap layer 110b of the lower charge storage layer 110. The charges may be implanted on or discharged from the upper charge trap pattern 114b of the first and second upper charge storage layers 117a and 118a. Consequently, operational efficiency and reliability of a memory device in a multi bit structure may be improved.

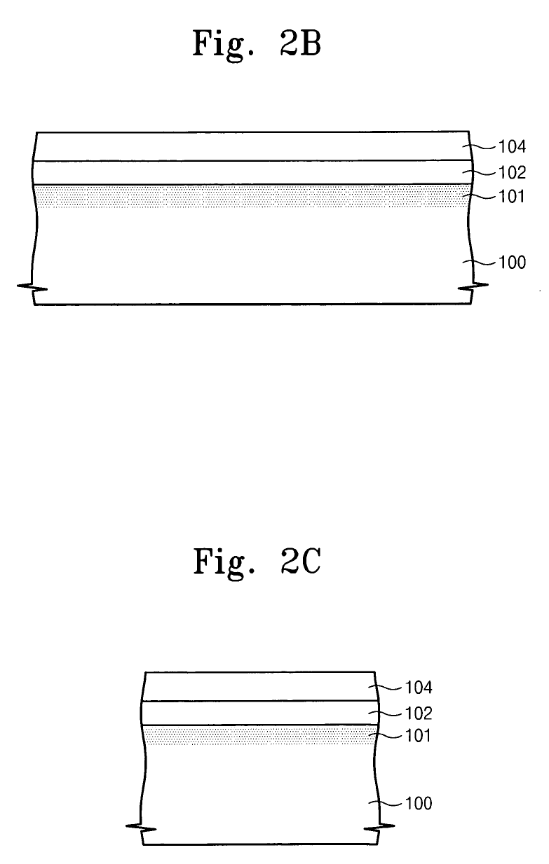

FIGS. 2A through 9A are plan views illustrating a method of fabricating a non-volatile memory device according to example embodiments. FIGS. 2B through 9B and 2C through 10C are sectional views taken along a dotted line X-X′ and a dotted line Y-Y′ of FIGS. 2A through 10A, respectively. Referring to FIGS. 2A-2C, a preliminary lower semiconductor substrate 100 may be prepared. The preliminary lower semiconductor substrate 100 may be a silicon substrate including a P-type impurity. A sacrificial layer 102 may be formed on the preliminary lower semiconductor substrate 100. The sacrificial layer 102 may have an etch selectivity with respect to the preliminary lower semiconductor substrate 100. For example, the sacrificial layer 102 may a silicon germanium layer having a lattice constant similar to that of the preliminary lower semiconductor substrate 100. The sacrificial layer 102 may be formed by performing an epitaxial growth process. According to example embodiments, an upper portion of the lower semiconductor substrate 100 may be used as a gate electrode by means of the lower high concentration impurity region 101.

An upper semiconductor layer 104 may be formed on the sacrificial layer 102. The upper semiconductor layer 104 may have an etch selectivity with respect to the sacrificial layer 102. For example, the upper semiconductor layer 104 may be a single crystal silicon layer that may be formed by performing an epitaxial growth process. The upper semiconductor layer 104 may include a seed semiconductor layer (not shown) on the sacrificial layer 102. The seed semiconductor layer may include the same material as the preliminary lower semiconductor substrate 100, and may be a crystalline silicon layer that may serve as a seed layer during an epitaxial growth process, e.g., forming the upper semiconductor layer 104.

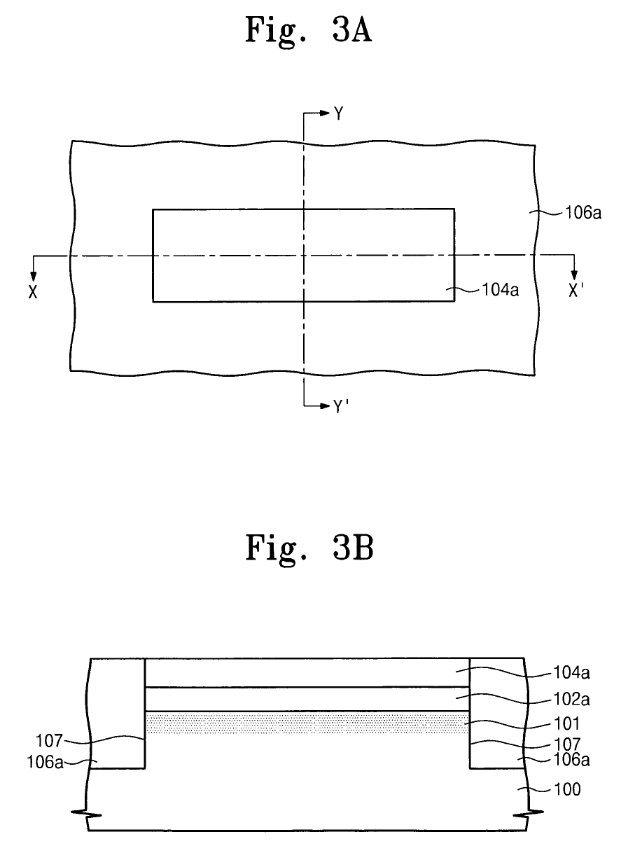

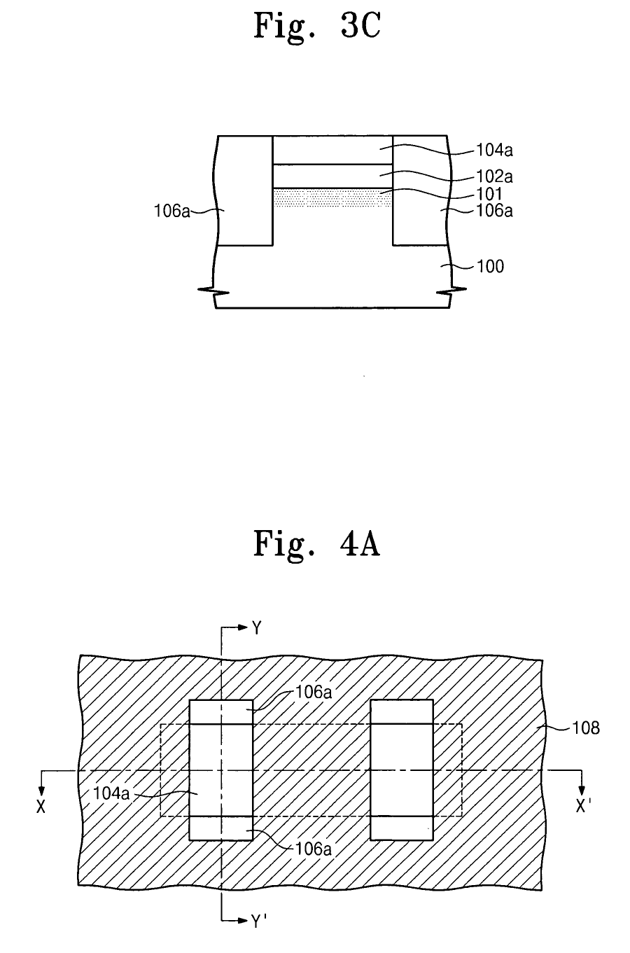

Referring to FIGS. 3A-3C, the upper semiconductor layer 104, the sacrificial layer 102, the preliminary lower semiconductor substrate 100 may be patterned to form a device isolation trench 107. An upper semiconductor pattern 104a, a sacrificial pattern 102a, and a lower semiconductor substrate 100 may be formed through the above patterning process. The device isolation trench 107 may be formed in the preliminary lower semiconductor substrate 100 through the upper semiconductor pattern 104a and the sacrificial pattern 102a. The device isolation insulation layer 106a may be formed to fill the device isolation trench 107. The device isolation insulation layer 106a may have an etch selectivity with respect to the upper semiconductor layer 104 and the sacrificial layer 102. For example, the device isolation insulation layer 106a may be a silicon oxide layer.

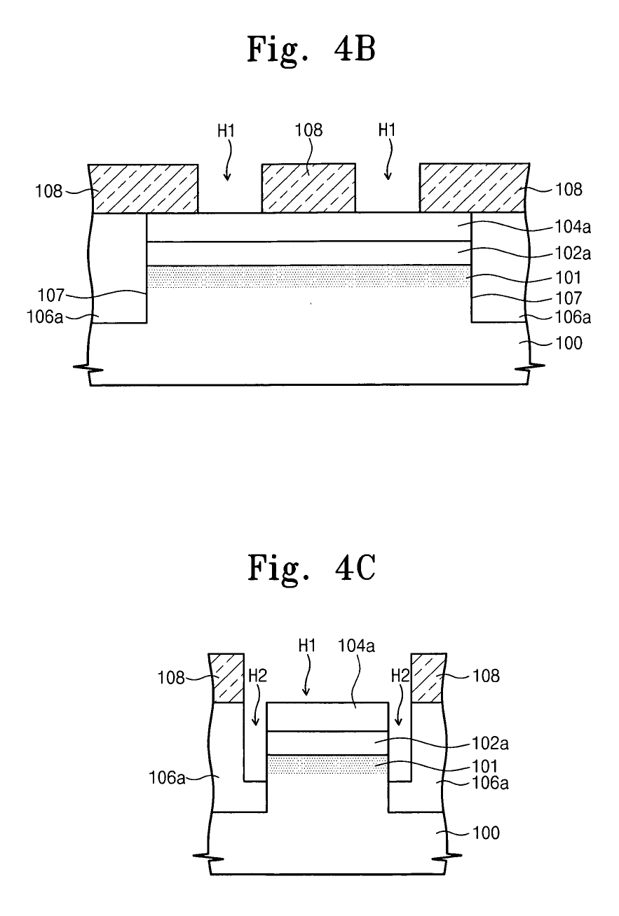

Referring to FIGS. 4A-4C, a first mask layer may be formed on the upper semiconductor pattern 104a and the device isolation insulation layer 106a. The first mask layer may have an etch selectivity with respect to the upper semiconductor pattern 104a, the sacrificial pattern 102a, and the device isolation insulation layer 106a. For example, the first mask layer may include a silicon nitride layer. The first mask layer may be patterned to form a first mask pattern 108 having a first groove H1. The first groove H1 may expose a portion of the device isolation insulation layer 106a that contacts the upper semiconductor pattern 104a. The first groove H1 may be provided singularly or in plurality. For example, as illustrated in the drawings, the first groove H1 may expose portions of the upper semiconductor pattern 104a and the device isolation layer 106a contacting the upper semiconductor pattern 104a.

Using the first mask pattern 108 and the upper semiconductor pattern 104a as an etch mask, the exposed device isolation insulation layer 106a may be selectively etched to form a second groove H2 that partially extends from the first groove H1. The second groove H2 may expose the side of the sacrificial pattern 102a and may be formed deeper than a region where the sacrificial pattern 102a is formed.

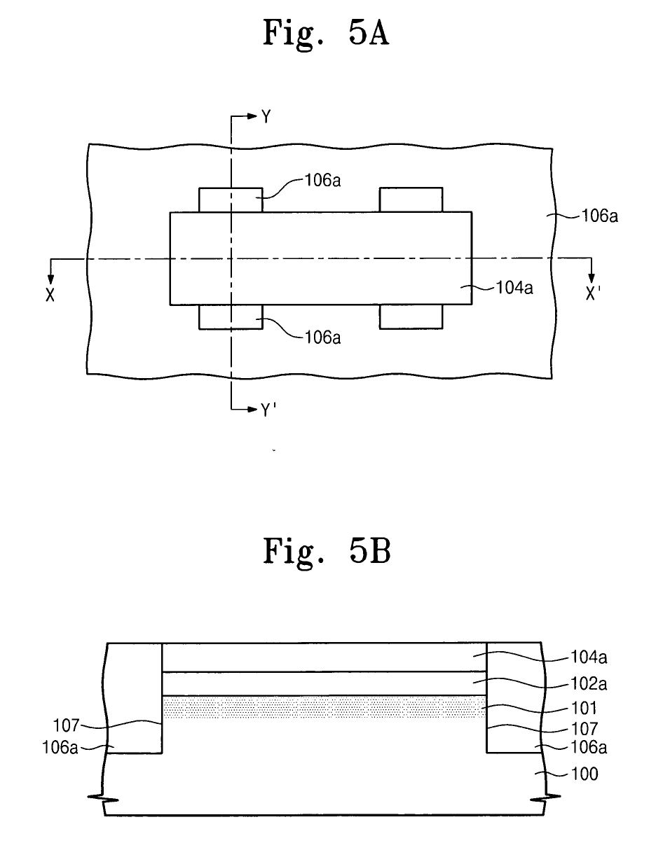

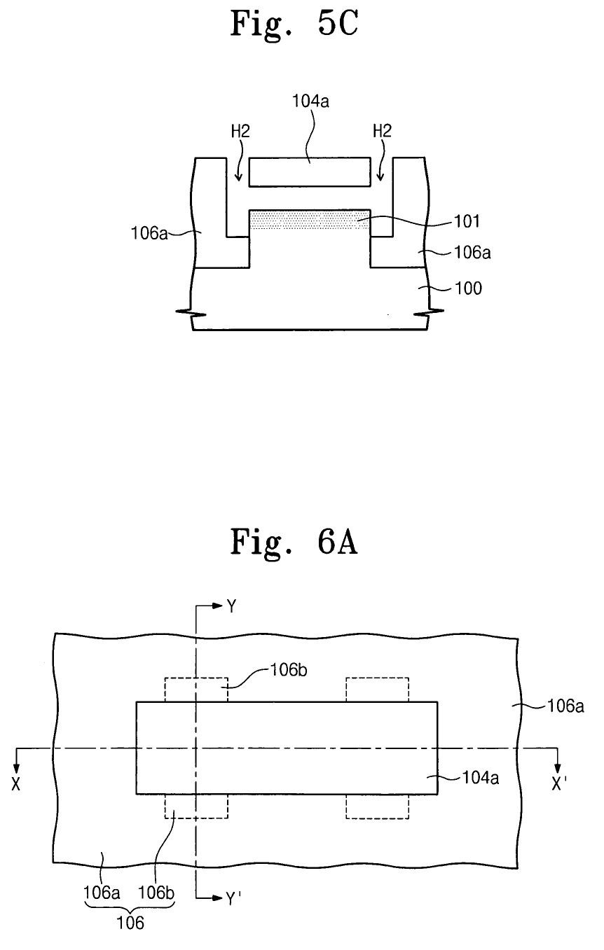

Referring to FIGS. 5A-5C, the exposed sacrificial pattern 102a may be removed to expose the bottom surface of the upper semiconductor pattern 104a and the top surface of the lower semiconductor substrate 100. The sacrificial pattern 102a may be removed by performing a selective isotropic etching process. The selective isotropic etching process may utilize different etching characteristics of different kinds of materials. Accordingly, the selective isotropic etching process may have improved etch selectivity compared to a method of using a defect density difference of the same material. Before or after removing the exposed sacrificial pattern 102a, the first mask pattern 108 may be removed.

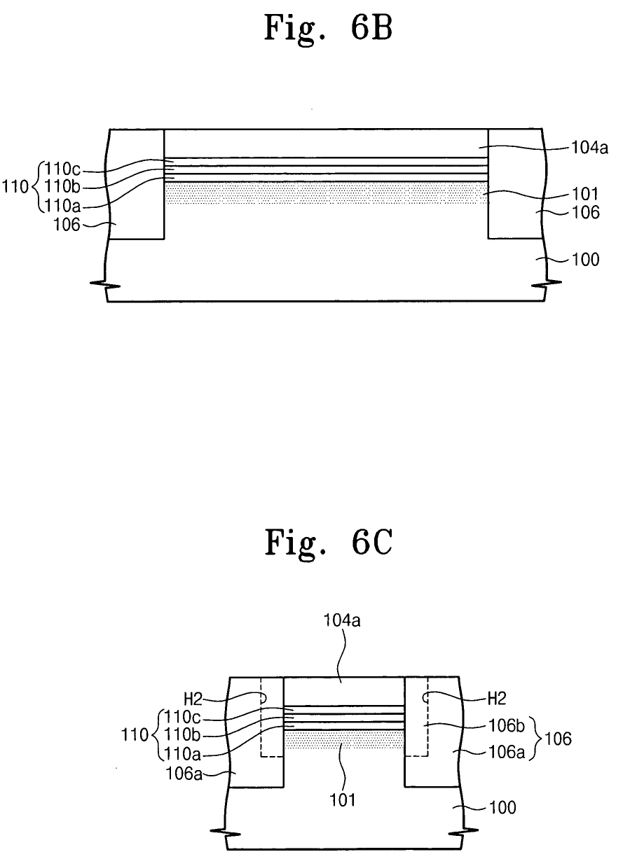

Referring to FIGS. 6A-6C, a lower tunnel insulation layer 110c on the bottom surface of the exposed upper semiconductor pattern 104a and a lower blocking layer 110a on the top surface of the exposed lower semiconductor substrate 100 may be formed. The lower tunnel insulation layer 110c and the lower blocking layer 110a may be formed simultaneously. The lower tunnel insulation layer 110c and the lower blocking layer 110a may be formed through a chemical vapor deposition (CVD) process. The lower tunnel insulation layer 110c may include a silicon oxide layer, a silicon oxide nitride layer, or a higher-k dielectric than the silicon oxide layer. The lower blocking layer 10a may be formed of at least one of higher-k materials than the silicon oxide layer. For example, the lower blocking layer 110a may include a multilayer having at least one of high-k dielectrics, e.g., an aluminum oxide layer, a hafnium oxide layer, a hafnium aluminum oxide layer, and a zirconium oxide layer. The lower tunnel insulation layer 110c and the lower blocking layer 110a may be a silicon oxide layer. The silicon oxide layer may be an MTO layer. Until a predetermined or given space remains between the upper tunnel insulation layer 10c and the lower blocking layer 110a, the deposition process may be performed. The lower tunnel insulation layer 110c and the lower blocking layer 110a may be formed by performing an atomic layer deposition (ALD) process.

A lower charge trap layer 110b may be formed between the lower tunnel insulation layer 110c and the lower blocking layer 110a. The lower charge trap layer 110b may include at least one of oxide layers of silicon, metal, and metal silicide and nitride layers of silicon, metal, and metal silicon. The lower charge trap layer 110b may further include conductive polysilicon dots that are two-dimensionally arranged on the lower tunnel insulation layer 110c. Forming the lower charge trap layer 110b may include forming a silicon nitride layer by performing a CVD process. The lower charge trap layer 110b may be formed by performing an ALD process. The lower blocking layer 110a, the lower charge trap layer 110b, and the lower tunnel insulation layer 110c may constitute a lower charge storage layer 110.

After forming the lower charge storage layer 110, an insulation layer 106b may be formed to fill the second groove H2. The insulation layer 106b may be a silicon oxide layer similar to the device isolation insulation layer 106a. The insulation layer 106b filled in the second groove H2 may be planarized until the upper semiconductor pattern 104a is exposed in order to form the device isolation pattern 106. The device isolation pattern 106 may define the upper semiconductor pattern 104a and the active regions of the lower semiconductor substrate 100. The active region may be the upper semiconductor pattern 104a.

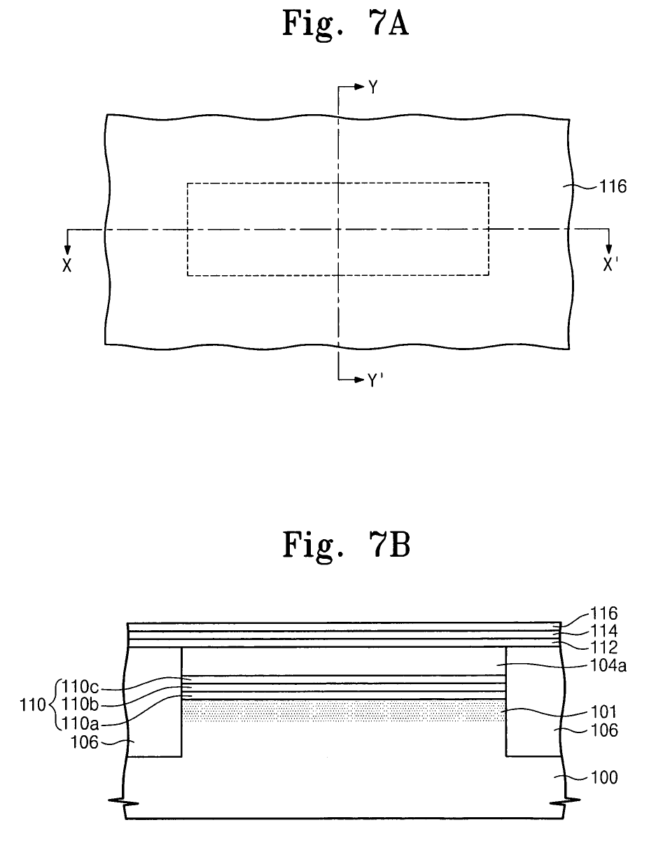

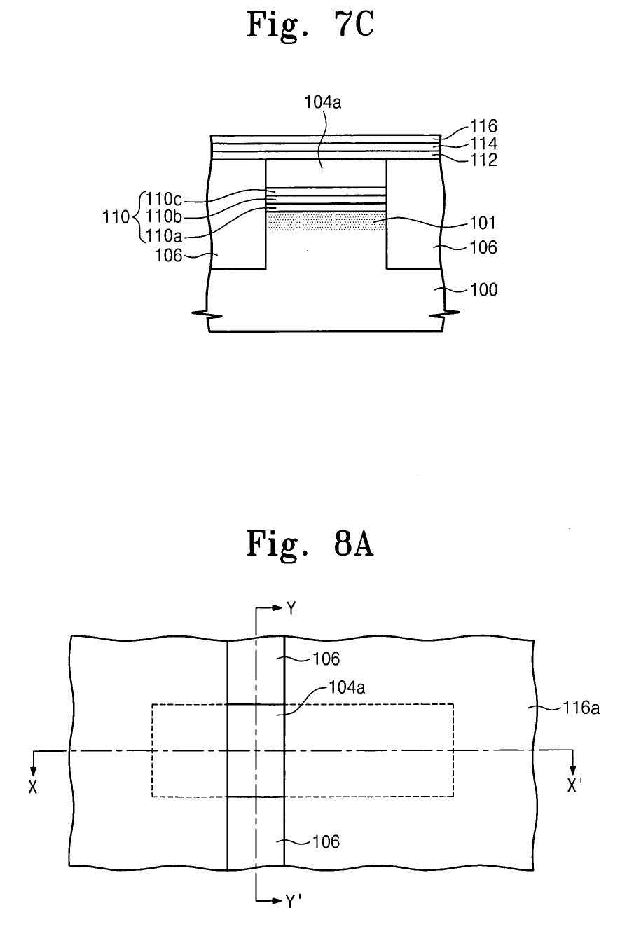

Referring to FIGS. 7A-7C, an upper tunnel insulation layer 112 may be formed on the upper semiconductor pattern 104a. For example, the upper tunnel insulation layer 112 may include a silicon oxide layer, a silicon oxide nitride layer, or a higher-k dielectric than the silicon oxide layer. Forming the upper tunnel insulation layer 112 may include forming a silicon oxide layer by performing a CVD process.

An upper charge trap layer 114 may be formed on the upper tunnel insulation layer 112. For example, the upper charge trap layer 114 may include at least one of oxide layers of silicon, metal, and silicide and nitride layers of silicon, metal, and silicide. The upper charge trap layer 114 may further include conductive polysilicon dots that are two-dimensionally arranged on the tunnel insulation layer 112. An upper blocking layer 116 may be formed on the upper charge trap layer 114. The upper blocking layer 116 may be formed of at least one of higher-k materials than a silicon oxide layer. For example, the upper blocking layer 116 may include at least one of high-k dielectrics, e.g., an aluminum oxide layer, a hafnium oxide layer, a hafnium aluminum oxide layer, and a zirconium oxide layer.

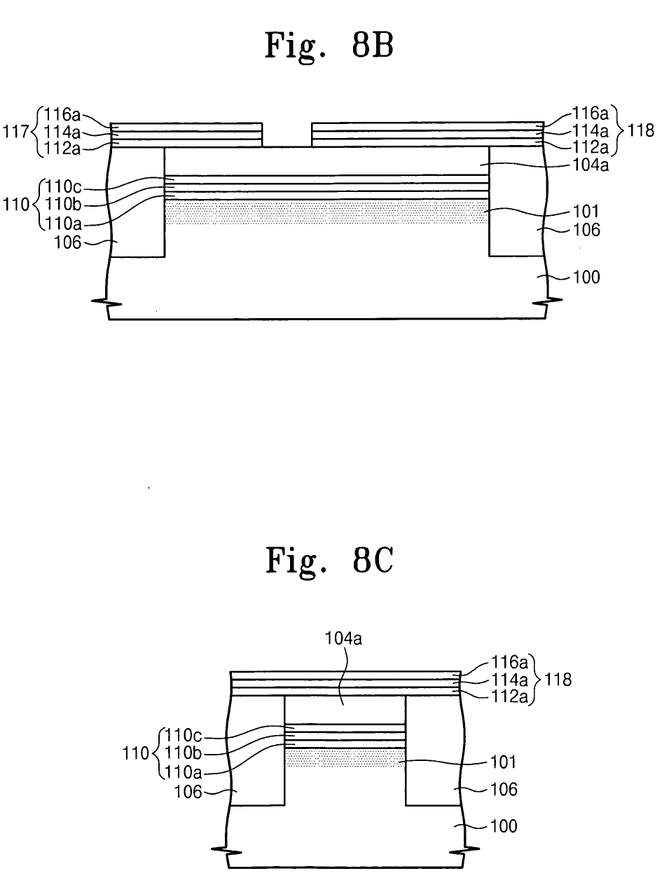

Referring to FIGS. 8A-8C, the upper blocking layer 116, the upper charge trap layer 114, and the upper tunnel insulation layer 112 may be patterned to form a first preliminary upper charge storage layer 117 and a preliminary second upper charge storage layer 118, which may be spaced apart from each other. The upper semiconductor pattern 104a may be exposed between the first preliminary upper charge storage layer 117 and the preliminary second upper charge storage layer 118. Each of the first preliminary upper charge storage layer 117 and the preliminary second upper charge storage layer 118 may include a preliminary upper blocking pattern 116a, a preliminary charge trap pattern 114a, and a preliminary upper tunnel insulation pattern 112a, which may be formed by the above patterning process.

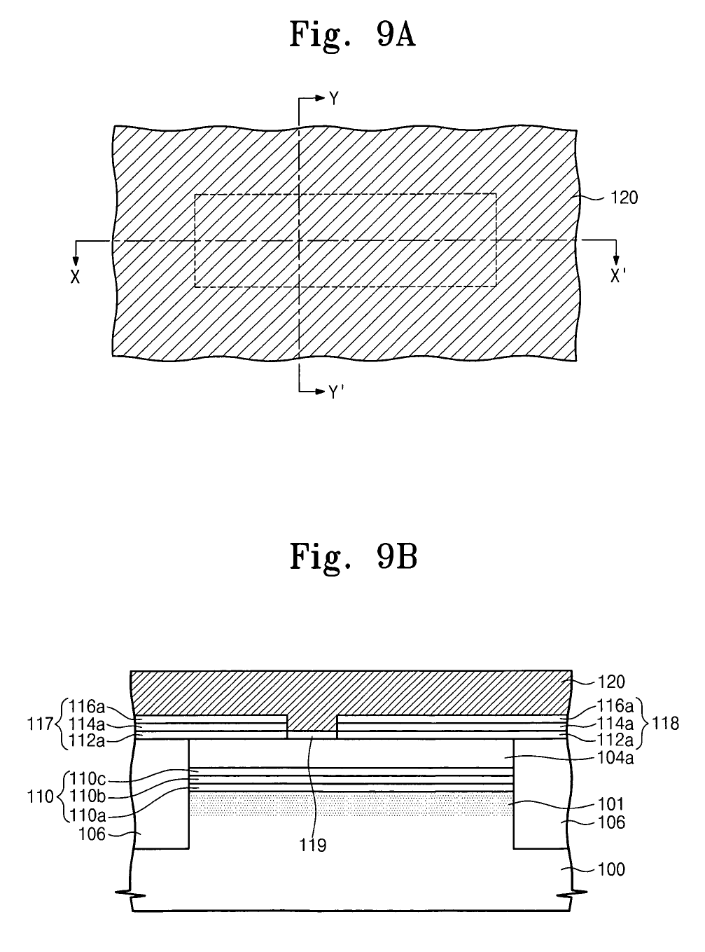

Referring to FIGS. 9A-9C, a gate insulation layer 119 may be formed on the exposed upper semiconductor pattern 104a. For example, the gate insulation layer 119 may be a silicon oxide layer that may be formed by performing a thermal oxidation layer process. The gate insulation layer 119 may be formed by performing a CVD process. A gate conductive layer 120 may be formed to cover the gate insulation layer 119, the preliminary first upper charge storage layer 117, and the preliminary upper charge storage layer 118. For example, the gate conductive layer 120 may include at least one of a metal layer, metal nitride layer, metal silicide layer, and polycrystalline silicon layer. The gate conductive layer 120 may include one of a tantalum nitride layer (TaN), a titanium nitride layer (TiN), a tungsten nitride layer (WN), and a polysilicon layer. The gate conductive layer 120 may be a poly silicon layer that is formed by performing a CVD process.

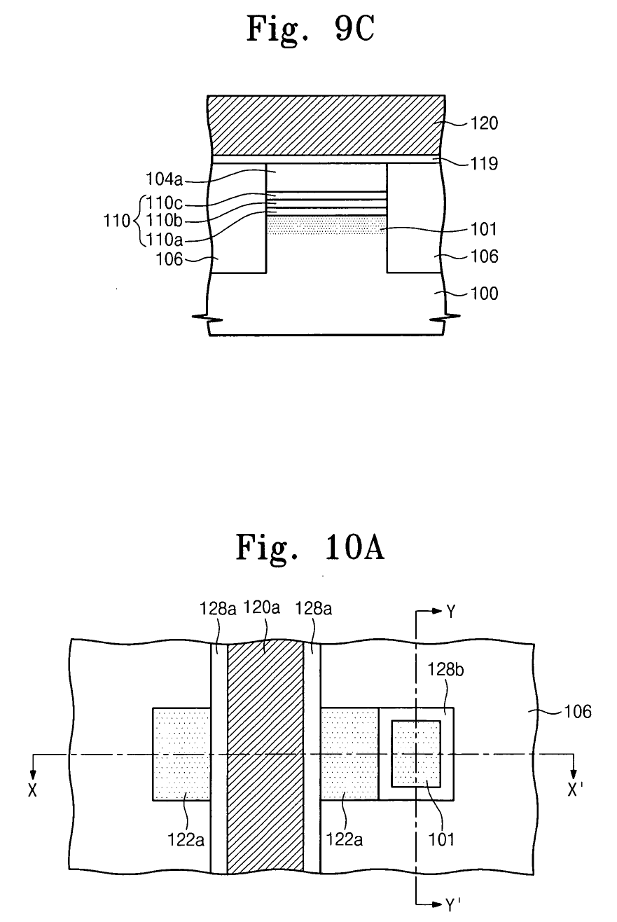

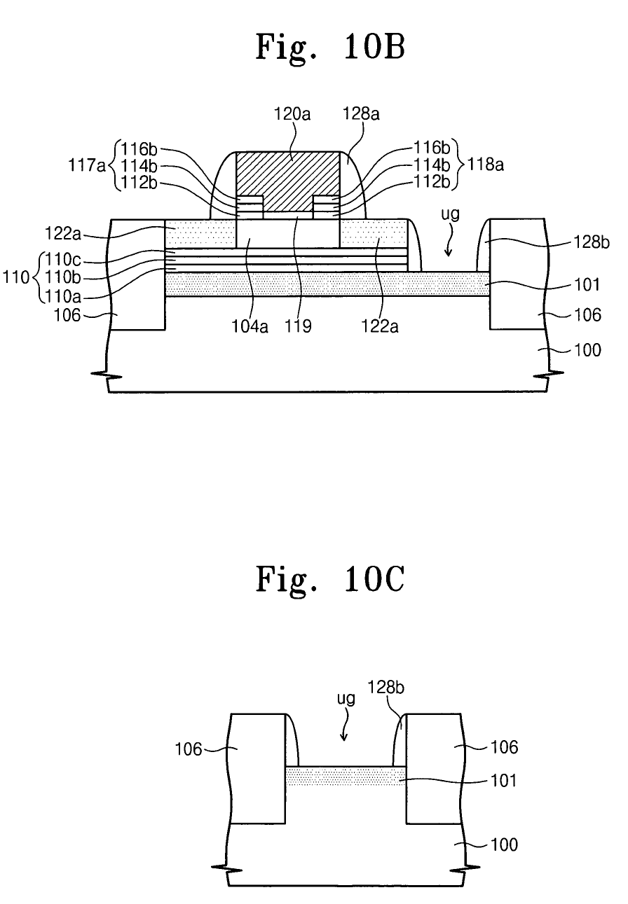

Referring to FIGS. 10A-10C, the gate conductive layer 120, the preliminary first upper charge storage layer 117, and the preliminary second upper charge storage layer 118 may be patterned to form a gate conductive pattern 120a, a first upper charge storage layer 117a, and a second upper charge storage layer 118a. The first upper charge storage layer 117a and the second upper charge storage layer 118a may be spaced apart from each other below the gate conductive pattern 120a. The first and second upper charge storage layers 117a and 118a may be aligned with the edges at both sidewalls of the gate conductive pattern 120a. The gate conductive pattern 120a may be a gate conductive structure. An ion implantation process may be performed on the upper semiconductor pattern 104a on both sides of the gate conductive structure 120a to form a low concentration impurity region 122a. The impurity may be an N-type.

A lower gate groove (ug) may be formed on the side of the upper semiconductor pattern 104a spaced apart from the gate conductive structure 120a. The lower gate groove (ug) may expose a lower high concentration impurity region 101 on an upper portion of the lower semiconductor substrate 100. The lower gate groove (ug) may be formed adjacent to the device isolation pattern 106.

A spacer layer may be conformally formed on the exposed lower high concentration impurity region 101 and on the gate conductive structure 120a. The spacer layer may have an etch selectivity with respect to the gate insulation layer 119. For example, the spacer layer may be a silicon nitride layer or a silicon oxide nitride layer SiON. The spacer layer may be anisotropically etched until the gate conductive structure 120a and the lower high concentration impurity region 101 are exposed, such that a first spacer 128a may be formed on both sidewalls of the gate conductive structure 120a, and a second spacer 128b may be formed on an inner wall of the lower gate groove (ug). The second spacer 128b may prevent or reduce electrical contact between source/drain regions and lower gate contacts, which will be formed during a subsequent process.

An ion implantation process may be performed on the upper semiconductor pattern 104a on both sides of the gate conductive structure 120a including the first spacer 128a. The impurity may be an N-type. The low concentration impurity region 122a and the high concentration impurity region 101 may constitute a source/drain region 122. The interlayer insulation layer 140 of FIG. 1 may be formed to cover the gate conductive structure 120a and the exposed lower high concentration impurity region 101. A lower gate contact hole 142 of FIG. 1 may penetrate through the interlayer insulation layer 140 to expose the lower high concentration impurity region 101. A conductive layer may be formed to fill the lower gate contact hole 142, such that the lower gate contact 144 may be formed. Contacts (not shown) may penetrate through the interlayer insulation layer 140 to be electrically connected to the gate conductive structure 120a and the source/drain region 122.

According to example embodiments, one cell-4 bit non-volatile memory device may be realized by including the first and second upper charge storage layers 117a and 118a and the lower charge storage layer 110 below the first and second upper charge storage layers 117a and 118a. On the other hand, if the charge trap layer is not separated, charges may be locally implanted on the charge trap layer adjacent to the source/drain region in order to be used for a non-volatile memory device of a multi bit structure. However, in a case of a memory device of a short channel, overlap phenomena may occur during charge implantation, and disturb phenomena may occur due to lateral diffusion of implanted charge.

According to example embodiments, because the first and second upper charge storage layers 117a and 118a are spaced apart from each other, overlap phenomena and disturb phenomena may be suppressed. According to example embodiments, an upper portion of the lower semiconductor substrate 100 may be used as a gate electrode by means of the lower high concentration impurity region 101. For example, a voltage may be independently applied to the upper portion of the lower semiconductor substrate 100. Accordingly, charges may be implanted on or discharged from the lower charge trap layer 110b of the lower charge storage layer 110. The charges may be implanted on or discharged from the upper charge trap pattern 114b of the first and second upper charge storage layers 117a and 118a. Consequently, operational efficiency and reliability of a memory device in a multi bit structure may be improved.

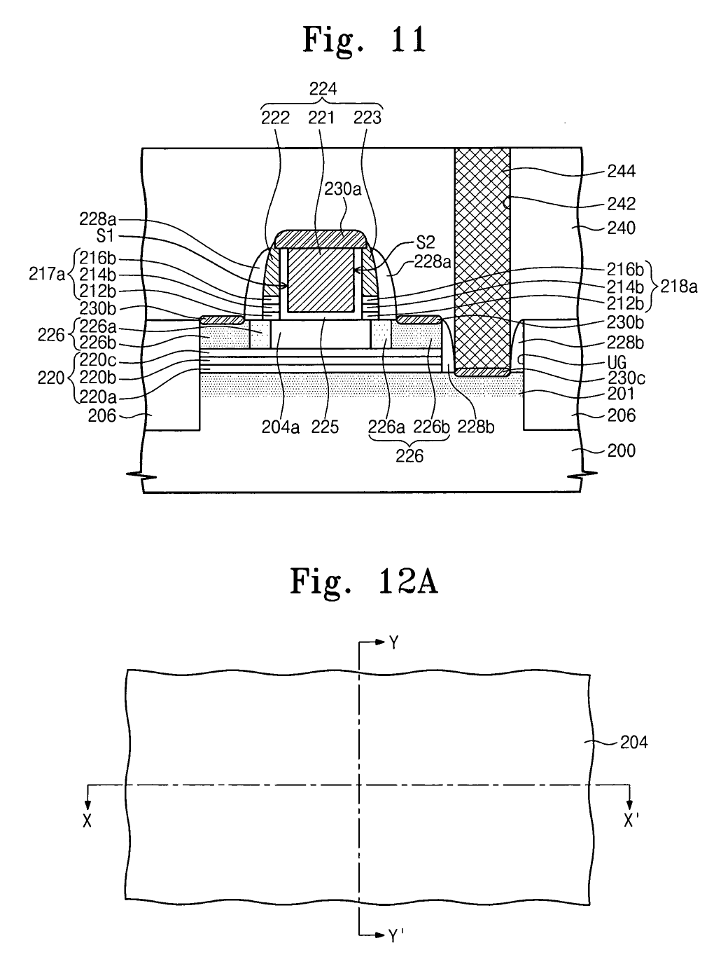

FIG. 11 is a non-volatile memory device according to example embodiments. A lower semiconductor substrate 200 may be provided. The lower semiconductor substrate 200 may be a silicon substrate including a P-type impurity. The lower high concentration impurity region 201 may be disposed in an upper portion of the lower semiconductor substrate 200. The impurity may be an N-type impurity. The lower high concentration impurity region 201 may be formed with a first depth along an upper surface of the lower semiconductor substrate 200. An upper semiconductor pattern 204a may be disposed on the lower semiconductor substrate 200. The upper semiconductor pattern 204a may be a single crystal silicon pattern. A lower charge storage layer 220 may be interposed between the upper semiconductor pattern 204a and the lower semiconductor substrate 200. The lower charge storage layer 220 may include a lower blocking layer 220a on the lower semiconductor substrate 200, a lower tunnel insulation layer 220c contacting the upper semiconductor pattern 204a on the lower blocking layer 220a, and a lower charge trap layer 220b between the lower blocking layer 220a and the lower tunnel insulation layer 220c. For example, the lower tunnel insulation layer 220c may include a silicon oxide layer, a silicon oxide nitride layer, or a higher-k dielectric than the silicon oxide layer.

The lower blocking layer 220a may be formed of at least one of higher-k materials than the silicon oxide layer. For example, the lower tunnel insulation layer 220c may include a silicon oxide layer, a silicon oxide nitride layer, or a higher-k dielectric than the silicon oxide layer. The lower blocking layer 220a may be formed of at least one of higher-k materials than the silicon oxide layer. For example, the lower blocking layer 220a may include a multilayer having at least one of high-k dielectrics, e.g., an aluminum oxide layer, a hafnium oxide layer, a hafnium aluminum oxide layer, and a zirconium oxide layer. The lower blocking layer 220a may be a silicon oxide layer. The silicon oxide layer may be an MTO layer. For example, the lower charge trap layer 220b may include at least one of oxide layers of silicon, metal, and metal silicide and nitride layers of silicon, metal, and metal silicon. The lower charge trap layer 220b may further include conductive polysilicon dots that may be two-dimensionally arranged on the lower tunnel insulation layer 220c.

A device isolation pattern 206 in the lower semiconductor substrate 200 and the upper semiconductor pattern 204a may define an active region. The active region may be the upper semiconductor pattern 204a. The gate conductive structure 224 may cross over the upper semiconductor pattern 204a. The gate conductive structure 224 may include a first gate conductive pattern 221, a second gate conductive pattern 222, and a third gate conductive pattern 223. A first spacer 228a may be prepared on both sidewalls of the gate conductive structure 224. The first spacer 228a may include a silicon nitride layer or a silicon oxide nitride layer (SiON).

The first gate conductive pattern 221 may cross over the upper semiconductor pattern 204a. The second and third gate conductive patterns 222 and 223 may be symmetrical to each other and facing the first gate conductive pattern 221. The second gate conductive pattern 222 may be adjacent to a first sidewall S1 of the first gate conductive pattern 221, and the third gate conductive pattern 223 may be adjacent to a second sidewall S2 of the first gate conductive pattern 221 facing the first sidewall S1. The first, second, and third gate conductive patterns 221, 222, and 223 may include at least one of a metal layer, a metal nitride layer, a metal silicide layer, and a polycrystalline silicon layer. For example, the first, second, and third gate conductive patterns 221, 222, and 223 may include one of a tantalum nitride layer (TaN), a titanium nitride layer (TiN), a tungsten nitride layer (WN), and a polysilicon layer. The first, second, and third gate conductive patterns 221, 222, and 223 may be doped poly silicon patterns.

The gate conductive structure 224 may include connection parts 230a on an upper portion of the first gate conductive pattern 221, on an upper portion of the second gate conductive pattern 222, and an upper portion of the third gate conductive pattern 223. The connection parts 230a may electrically connect the first, second and third gate conductive patterns 221, 222, and 223. For example, if the first, second and third gate conductive patterns 221, 222, and 223 are a polysilicon pattern, the connection parts 230a may include a metalized material, e.g., a metal silicide. The gate conductive structure 224 may include a first spacer on outer sidewalls of the second gate conductive pattern 222 and the third gate conductive pattern 223.

The first upper charge storage layer 217a and the second upper charge storage layer 218a may be spaced apart from each other between the gate conductive structure 224 and the upper semiconductor pattern 204a. The first gate conductive pattern 221 may be disposed between the first upper charge storage layer 217a and the second upper charge storage layer 218a. The first upper charge storage layer 217a may be disposed between the second gate conductive pattern 222 and the upper semiconductor pattern 204a, and the second upper charge storage layer 218a may be disposed between the third gate conductive pattern 223 and the upper semiconductor pattern 204a. The first upper charge storage layer 217a may be aligned below the second gate conductive pattern 222 and with an outer sidewall edge of the second gate conductive pattern 222. The second upper charge storage layer 218a may be aligned below the third gate conductive pattern 223 and with an outer sidewall of the third gate conductive pattern 223.

Each of the first and second upper charge storage layers 217a and 218a may include an upper tunnel insulation pattern 212b on the upper semiconductor pattern 204a, an upper charge trap pattern 214b on the upper tunnel insulation pattern 212b, and an upper blocking insulation pattern 216b on the upper charge trap pattern 214b. The upper charge trap pattern 214b may include at least one of oxide layers of silicon, metal, and silicide and nitride layers of silicon, metal, and silicide. The upper charge trap pattern 214b may further include conductive polysilicon dots that are two-dimensionally arranged on the upper tunnel insulation pattern 212b.

A gate insulation layer 225 may be interposed between the upper semiconductor pattern 204a and the first gate conductive pattern 221, between the first sidewall S1 and the second gate conductive pattern 222, between the first sidewall S1 and the second gate conductive pattern 222, and between the second sidewall S2 and the third gate conductive pattern 223. The source/drain region 226 may be disposed in the upper semiconductor pattern 204a on both sides of the gate conductive structure 224. The source/drain region 226 may include a low concentration impurity region 226a and a high concentration impurity region 226b. The impurity may be an N-type. A metal silicide 230b may be disposed on the top surface of the source/drain region 226. A metal silicide layer 230c may be formed on the top surface of the lower high concentration impurity region 201 that is exposed by the lower gate groove UG. The metal silicide layers 230b and 230c may be formed simultaneously.

A lower gate groove (UG) may be spaced apart from the gate conductive structure 224 and may be disposed adjacent to the device isolation pattern 206. The lower gate groove (UG) may expose the lower high concentration impurity region 201. A second spacer 228b may be disposed on an inner wall of the lower gate groove UG. The second spacer 228b may include a silicon nitride layer or a silicon oxide nitride layer (SiON).

An interlayer insulation layer 240 may cover the gate conductive structure 224 and the exposed lower high concentration impurity region 201. A lower gate contact hole 242 may penetrate through the interlayer insulation layer 240 to expose the lower high concentration impurity region 201. A lower gate contact 244 may fill the lower gate contact hole 242, and may be electrically connected to the lower high concentration impurity region 201. The second spacer 228b may prevent or reduce electrical contact between the source/drain region 226 and the lower gate contact 224. Contacts (not shown) may be formed to be electrically connected to the gate conductive structure 224 and the source/drain region 226 through the interlayer insulation layer 240. Unlike example embodiments illustrated in FIG. 1, the first upper charge storage layer 217a and the second upper charge storage layer 218b may substantially have the same length. Accordingly, a difference of a threshold voltage shift may become smaller, such that reliability of a non-volatile memory device may be improved.

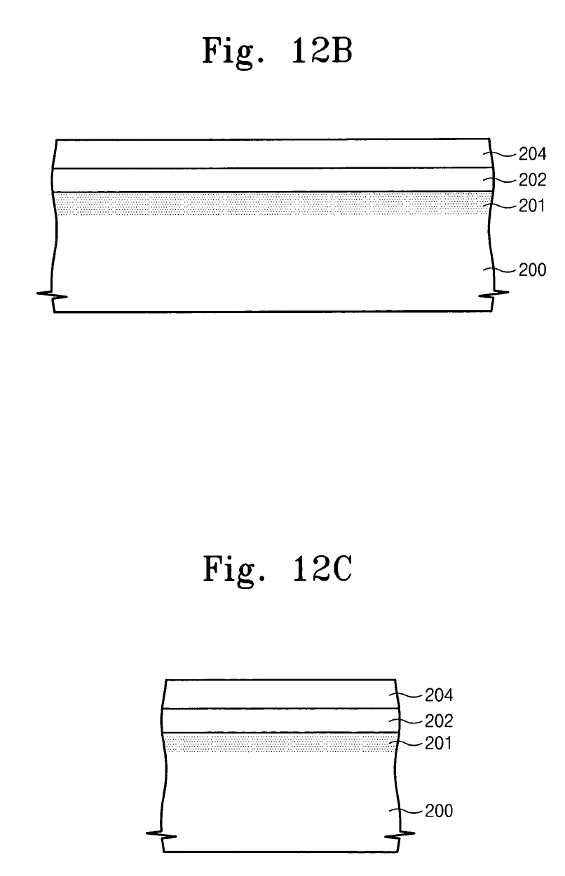

FIGS. 12A-21A are plan views illustrating a method of fabricating a non-volatile memory device according to example embodiments. FIGS. 11B-19B and 11C-19C are sectional views taken along a dotted line X-X′ and a dotted line Y-Y′ of FIGS. 11A-19A, respectively. Referring to FIGS. 12A-12C, a preliminary semiconductor substrate 200 may be provided. The preliminary semiconductor substrate 200 may be a silicon substrate including a P-type impurity. A lower high concentration impurity region 201 may be formed with a first depth along an upper surface of the preliminary semiconductor substrate 200. The lower high concentration impurity region 201 may be a region where an N-type impurity may be implanted.

A sacrificial layer 202 may be formed on the preliminary semiconductor substrate 200 having the lower high concentration region 201. The sacrificial layer 202 may have an etch selectivity with respect to the preliminary semiconductor substrate 200. For example, the sacrificial layer 202 may be a silicon germanium layer having a lattice constant similar to that of the preliminary semiconductor substrate 200. The sacrificial layer 202 may be formed by performing an epitaxial growth process.

An upper semiconductor layer 204 may be formed on the sacrificial layer 202. The upper semiconductor layer 204 may have an etch selectivity with respect to the sacrificial layer 202. For example, the upper semiconductor layer 204 may be a single crystal silicon layer formed by performing an epitaxial growth process. The upper semiconductor layer 204 may include a seed semiconductor layer (not shown) on the sacrificial layer 202. The seed semiconductor layer may include the same material as the preliminary lower semiconductor substrate 200, and may be a crystalline silicon layer that may serve as a seed layer during an epitaxial growth process, e.g., forming the upper semiconductor layer 204.

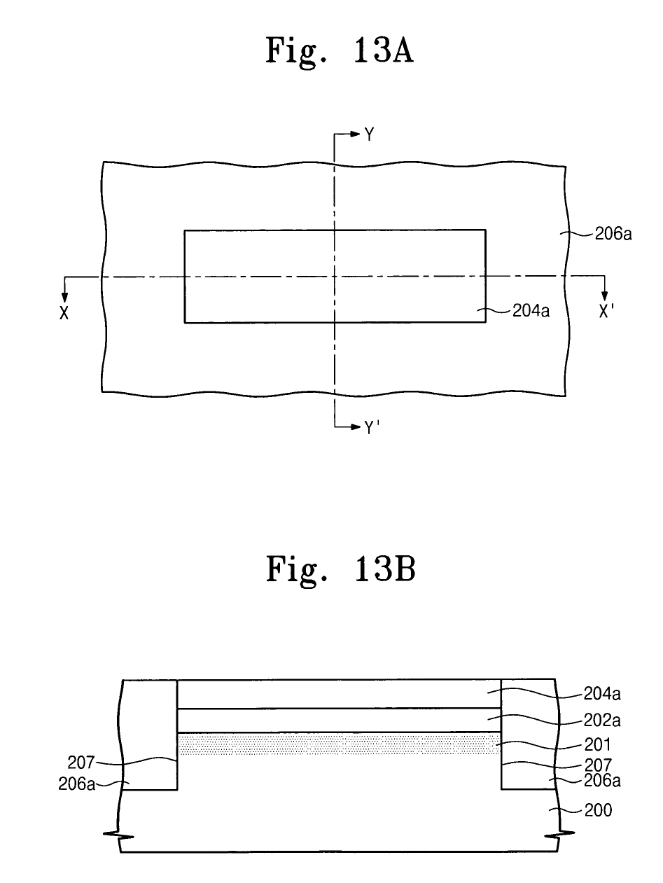

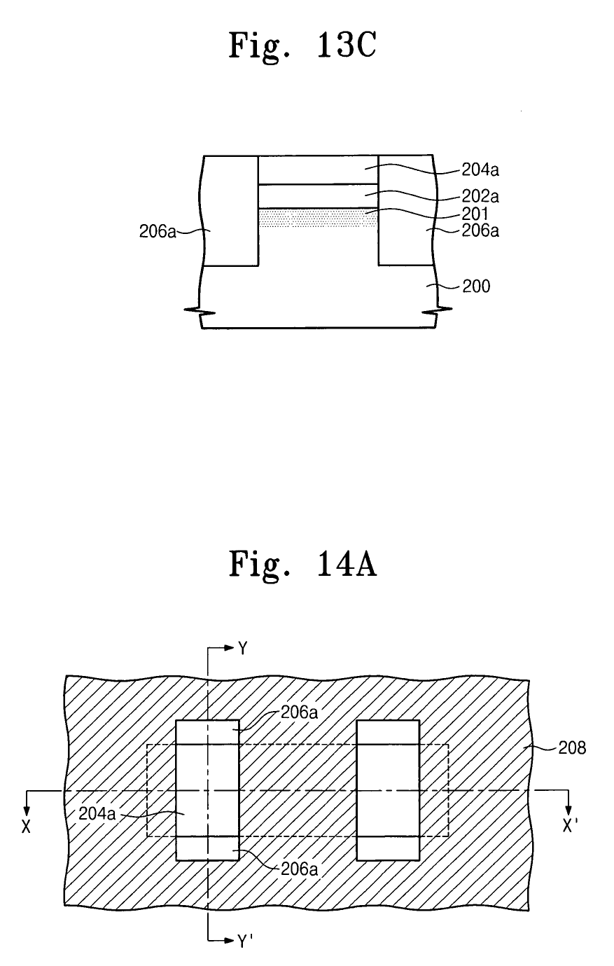

Referring to FIGS. 13A-13C, the upper semiconductor layer 204, the sacrificial layer 202, the preliminary lower semiconductor substrate 200 may be patterned to form a device isolation trench 207. An upper semiconductor pattern 204a, a sacrificial pattern 202a, and a lower semiconductor substrate 200 may be formed through the above patterning. The device isolation trench 207 may be formed deeper than the lower high concentration impurity region 201 having the first depth through the upper semiconductor pattern 204a and the sacrificial pattern 202a at an upper portion of the lower semiconductor substrate 200. The device isolation insulation layer 206a may be formed to fill the device isolation trench 207. The device isolation insulation layer 206a may have an etch selectivity with respect to the upper semiconductor layer 204 and the sacrificial layer 202. For example, the device isolation insulation layer 206a may be a silicon oxide layer.

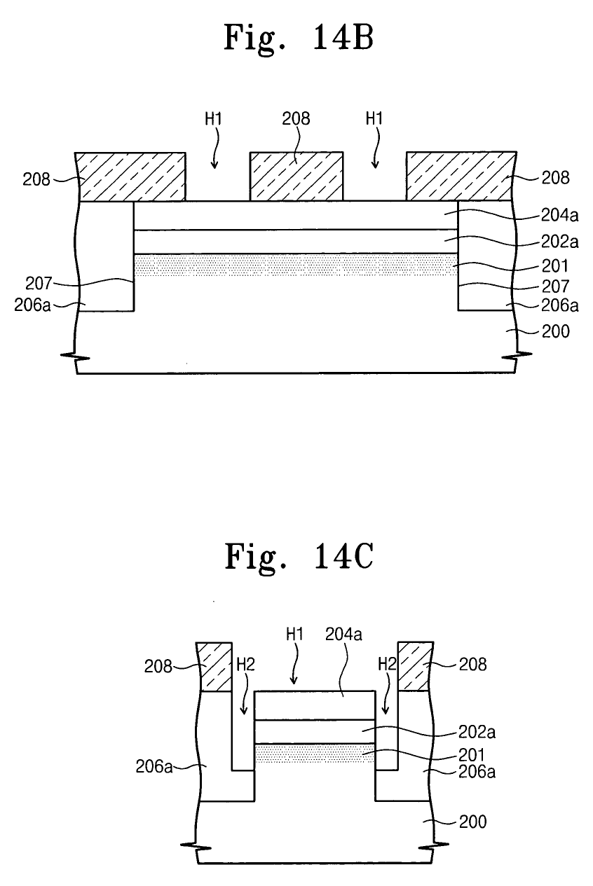

Referring to FIGS. 14A-14C, a first mask layer may be formed on the upper semiconductor pattern 204a and the device isolation insulation layer 206a. The first mask layer may have an etch selectivity with respect to the upper semiconductor pattern 204a, the sacrificial pattern 202a, and the device isolation insulation layer 206a. For example, the first mask layer may include a silicon nitride layer.

The first mask layer may be patterned to form a first groove H1. The first groove H1 may expose a portion of the device isolation insulation layer 206a that contacts the upper semiconductor pattern 204a. The first groove H1 may expose a portion of the upper semiconductor pattern 204a. The first groove H1 may be provided singularly or in plurality. For example, as illustrated in the drawings, the first groove H1 may expose a portion of the upper semiconductor layer 204a and a portion of the device isolation insulation layer 206a contacting a portion of the upper semiconductor pattern 204a.

Using the first mask pattern 208 and the upper semiconductor pattern 204a as an etch mask, the exposed device isolation insulation layer 206a may be selectively etched to form a second groove H2 that partially extends from the first groove H1. The second groove H2 may expose the side of the sacrificial pattern 202a and may be formed deeper than a region where the sacrificial pattern 202a may be formed.

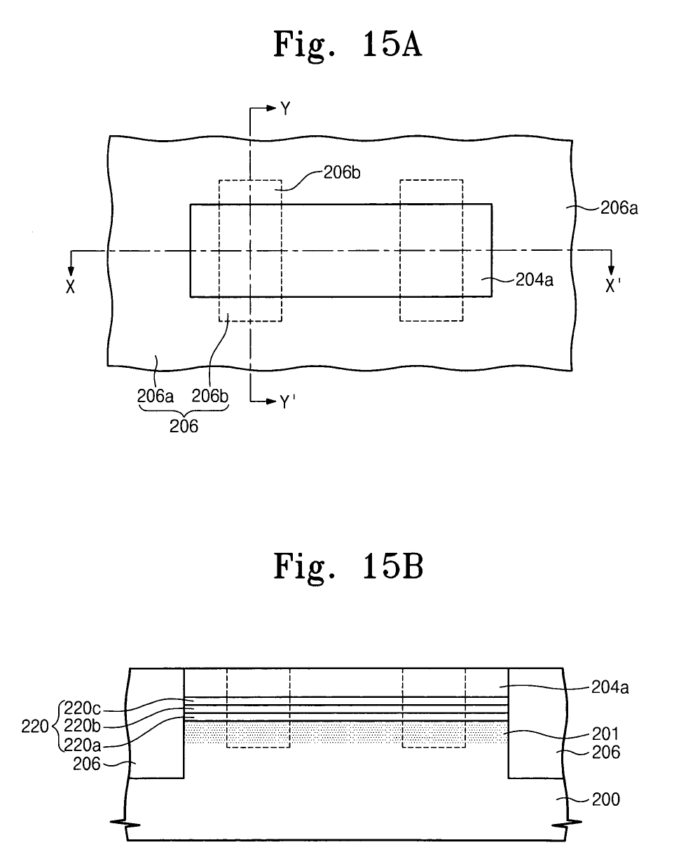

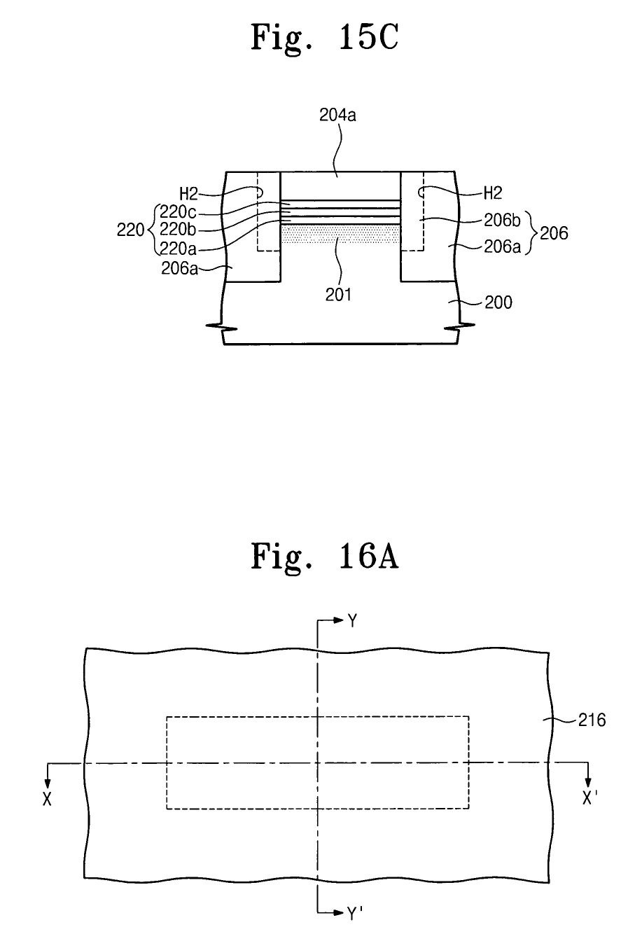

Referring to FIGS. 15A-15C, the exposed sacrificial pattern 202a may be removed to expose the bottom surface of the upper semiconductor pattern 204a and the top surface of the lower semiconductor substrate 200. The sacrificial pattern 202a may be removed by performing a selective isotropic etching process. The selective isotropic etching process may utilize different etching characteristics of different types of materials. Accordingly, the selective isotropic etching process may have improved etch selectivity compared to a method of using a defect density difference of the same material. Before removing the exposed sacrificial pattern 202a, the first mask pattern 208 may be removed.

A lower tunnel insulation layer 220c on the bottom surface of the exposed upper semiconductor pattern 204a and a lower blocking layer 220a on the top surface of the exposed lower semiconductor substrate 200 may be formed. The lower tunnel insulation layer 220c and the lower blocking layer 220a may be formed simultaneously. The lower tunnel insulation layer 220c and the lower blocking layer 220a may be formed through a CVD process. For example, the lower tunnel insulation layer 220c may include a silicon oxide layer, a silicon oxide nitride layer, or a higher-k dielectric than the silicon oxide layer. The lower blocking layer 220a may be formed of at least one of higher-k materials than the silicon oxide layer. For example, the lower blocking layer 220a may include a multilayer having at least one of high-k dielectrics, e.g., an aluminum oxide layer, a hafnium oxide layer, a hafnium aluminum oxide layer, and a zirconium oxide layer.

The lower tunnel insulation layer 220c and the lower blocking layer 220a may be a silicon oxide layer. The silicon oxide layer may be an MTO layer. Until a predetermined or given space remains between the upper tunnel insulation layer 220c and the lower blocking layer 220a, the deposition process may be performed. The lower tunnel insulation layer 220c and the lower blocking layer 220a may be formed by performing an ALD process.

A lower charge trap layer 220b may be formed between the lower tunnel insulation layer 220c and the lower blocking layer 220a. The lower charge trap layer 220b may include at least one of oxide layers of silicon, metal, and metal silicide and nitride layers of silicon, metal, and metal silicon. The lower charge trap layer 220b may further include conductive polysilicon dots that are two-dimensionally arranged on the lower tunnel insulation layer 220c. The lower charge trap layer 220b may be a silicon nitride layer that is formed by performing a CVD process. The lower charge trap layer 220b may be formed by performing an ALD process. The lower blocking layer 220a, the lower charge trap layer 220b, and the lower tunnel insulation layer 220c may constitute a lower charge storage layer 220.

After forming the lower charge storage layer 220, an insulation layer 206b may be formed to fill the second groove H2. The insulation layer 206b may be a silicon oxide layer like the device isolation insulation layer 206a. The insulation layer 206b filled in the second groove H2 may be planarized until the upper semiconductor pattern 204a is exposed in order to form the device isolation pattern 206. The device isolation pattern 206 may define the upper semiconductor pattern 204a and the active regions of the lower semiconductor substrate 200. The active region may be the upper semiconductor pattern 204a.

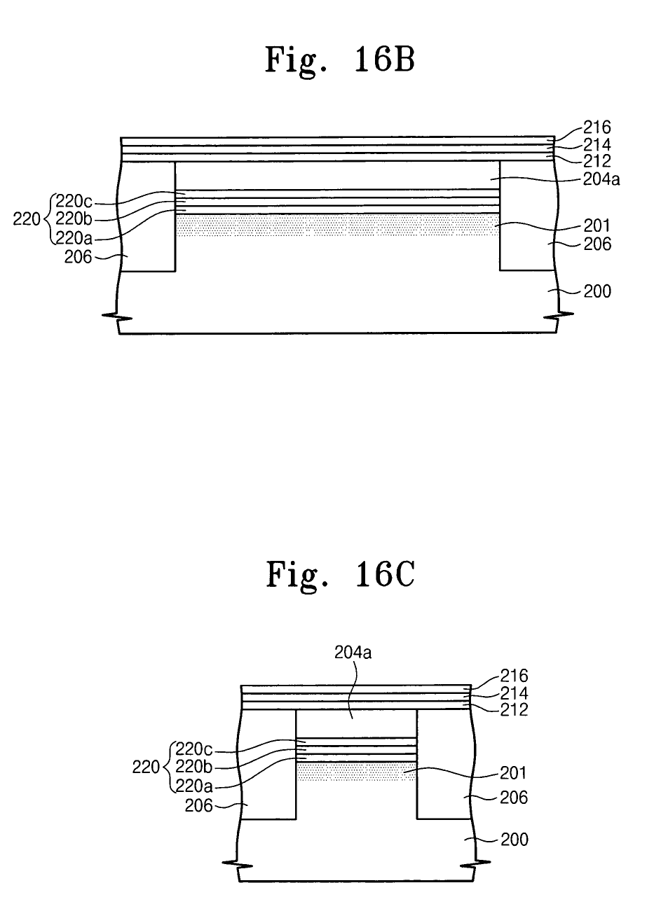

Referring to FIGS. 16A-16C, an upper tunnel insulation layer 212 may be formed on the upper semiconductor pattern 204a. The upper tunnel insulation layer 212 may include a silicon oxide layer, a silicon oxide nitride layer, or a higher-k dielectric than the silicon oxide layer. The upper tunnel insulation layer 212 may be a silicon oxide layer formed by performing a chemical vapor deposition process. An upper charge trap layer 214 may be formed on the upper tunnel insulation layer 212. The upper charge trap layer 214 may include at least one of oxide layers of silicon, metal, and silicide and nitride layers of silicon, metal, and silicide. The upper charge trap layer 214 may further include conductive polysilicon dots that may be two-dimensionally arranged on the tunnel insulation layer 212. An upper blocking layer 216 may be formed on the upper charge trap layer 214. The upper blocking layer 216 may be formed of at least one of higher-k materials than a silicon oxide layer. For example, the upper blocking layer 216 may include at least one of high-k dielectrics, e.g., an aluminum oxide layer, a hafnium oxide layer, a hafnium aluminum oxide layer, and a zirconium oxide layer.

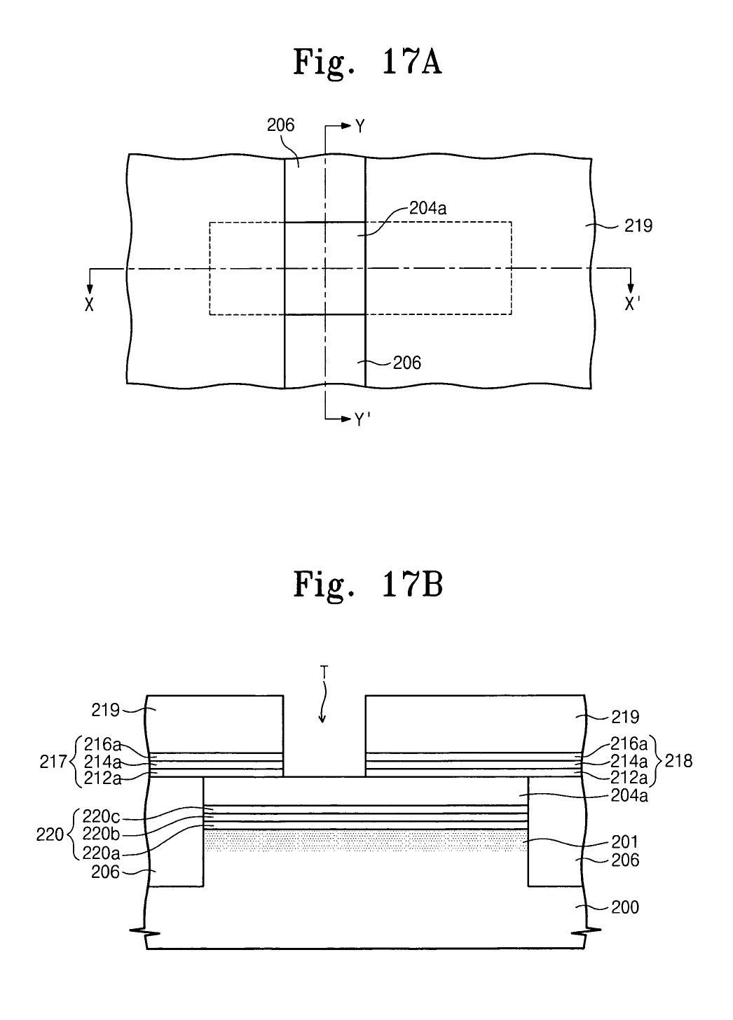

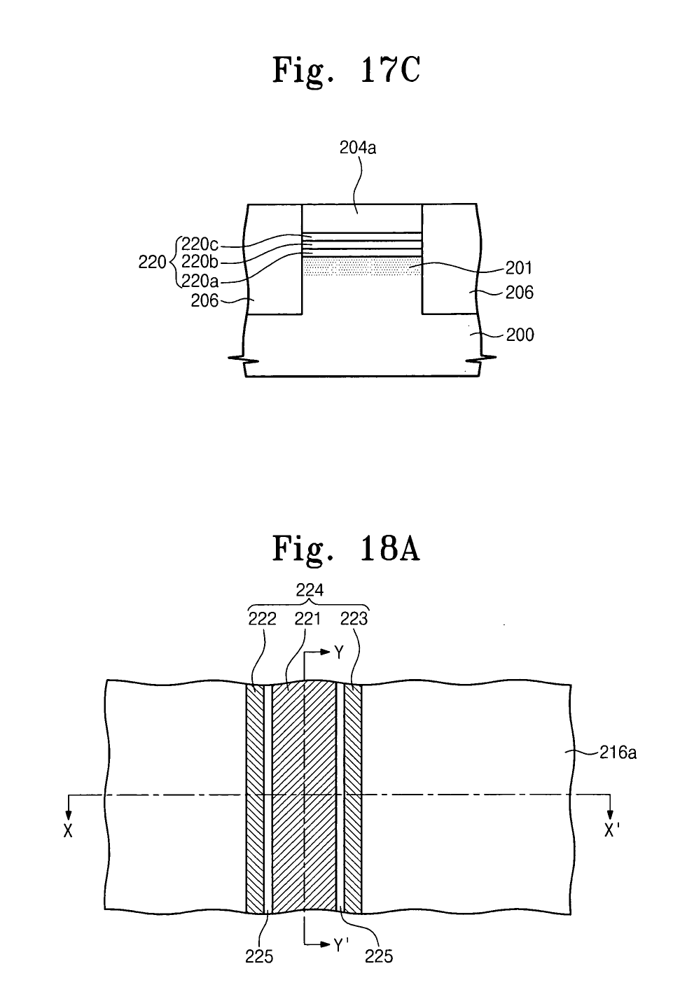

Referring to FIGS. 17A-17C, a second mask layer (not shown) may be formed on the upper blocking layer 216. The second mask layer may have an etch selectivity with respect to the upper blocking layer 216. The second mask layer may be a silicon nitride layer. A photoresist pattern (not shown) may be formed on the second mask layer. Using the photoresist pattern as an etch mask, the second mask layer, the upper blocking layer 216, the upper charge trap layer 214, and the upper tunnel insulation layer 212 may be anisotropically etched to form a trench T. The trench T may expose the upper semiconductor pattern 204a.

Through the anisotropic etching process, a preliminary first upper charge storage layer 217 and a preliminary second upper charge storage layer 218 may be formed to be spaced apart from each other and may have the trench T therebetween. A second mask pattern 219 may be formed on the preliminary first upper charge storage layer 217 and the preliminary second upper charge storage layer 218. Each of the preliminary first upper charge storage layer 217 and the preliminary second upper charge storage layer 218 may include an anisotropically-etched preliminary upper blocking pattern 216a, preliminary upper charge trap pattern 214a, and preliminary upper tunnel insulation pattern 212a.

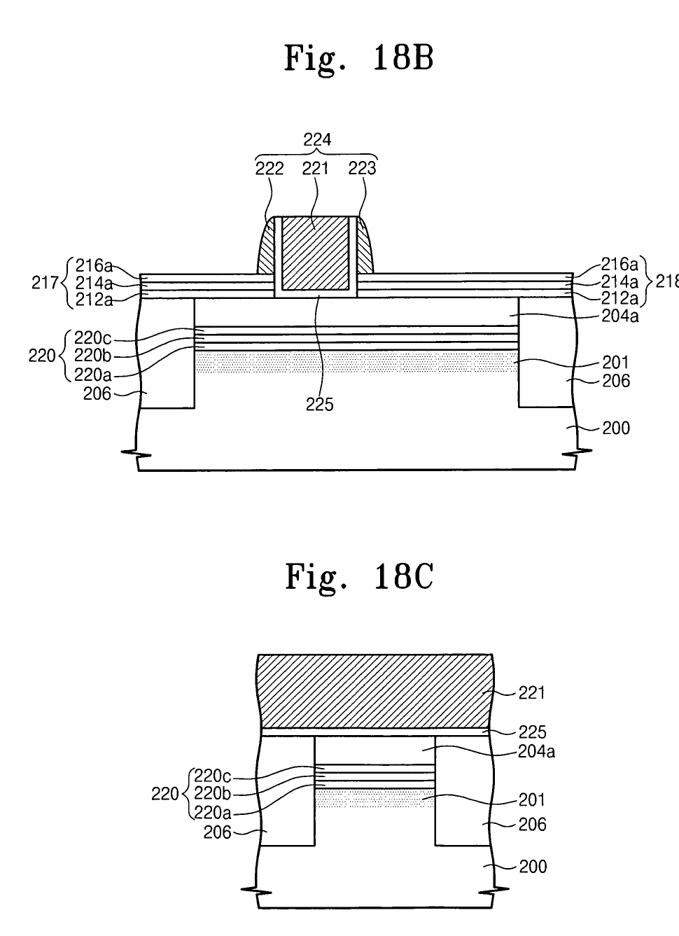

Referring to FIGS. 18A-18C, a gate insulation layer 225 may be formed on the exposed upper semiconductor pattern 204a and on an inner wall of the trench T. The gate insulation layer 225 may have an etch selectivity with respect to the second mask pattern 219. For example, the gate insulation layer 225 may be a silicon oxide layer formed by performing a CVD process. A first gate conductive layer (not shown) may be formed to fill the trench T including the gate insulation layer 225, and then a planarization process may be performed to form a first gate conductive pattern 221.

The first gate conductive pattern 221 may have an etch selectivity with respect to the second mask pattern 219. For example, the first gate conductive layer may include at least one of a metal layer, a metal nitride layer, a metal silicide layer, and a polycrystalline silicon layer. For example, the gate conductive layer may include one of a tantalum nitride layer (TaN), a titanium nitride layer (TiN), a tungsten nitride layer (WN), and a polysilicon layer. The first gate conductive layer may be a polysilicon layer formed by performing a CVD process. The second mask pattern 219 may be removed to expose the preliminary upper blocking pattern 216a of the preliminary first and second charge storage layers 217 and 218. The second mask pattern 219 may be removed by an isotropic etching process.

A second gate conductive layer (not shown) may be conformally formed on an upper semiconductor pattern 204a including the exposed preliminary upper blocking pattern 216a. For example, the second gate conductive layer may include at least one of a metal layer, a metal nitride layer, a metal silicide layer, and a polycrystalline silicon layer. For example, the gate conductive layer may include one of a tantalum nitride layer (TaN), a titanium nitride layer (TiN), a tungsten nitride layer (WN), and a polysilicon layer. The second gate conductive layer may be a polysilicon layer formed by performing a CVD process. The second gate conductive layer may be anisotropically etched until the first gate conductive pattern 221 is exposed in order to form a second gate conductive pattern 222 and a third gate conductive pattern 223. The second and third gate conductive patterns 222 and 223 may be symmetrical and face the first gate conductive pattern 221. The second and third gate conductive patterns 222 and 223 may substantially have the same spacer shape. The first, second, and third gate conductive patterns 221, 222, and 223 may constitute a gate conductive structure 224.

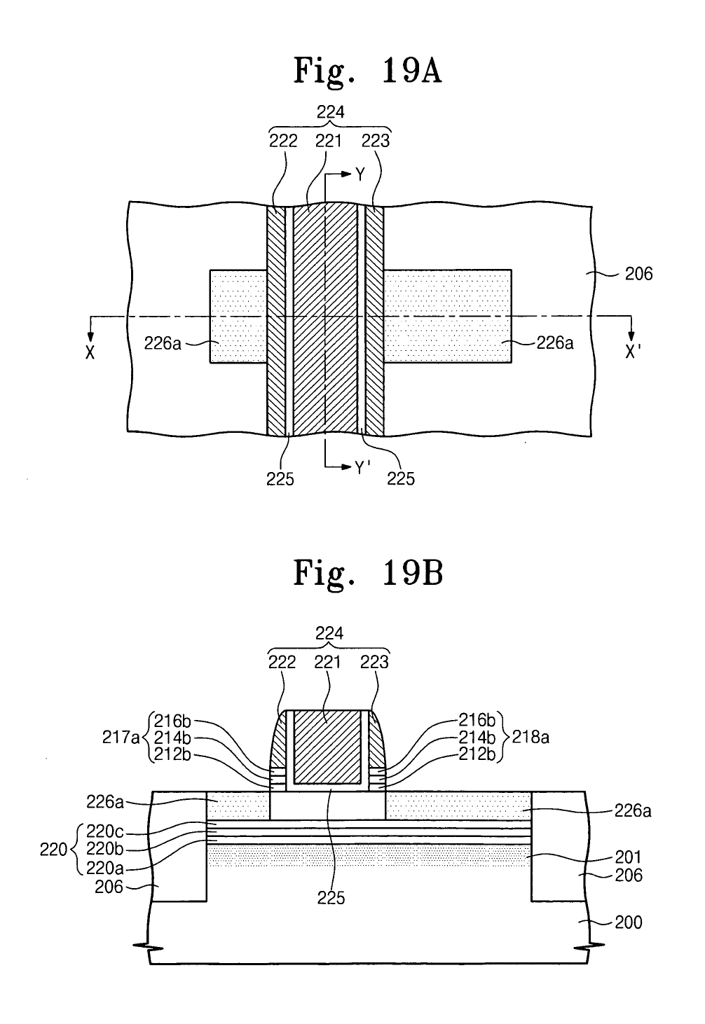

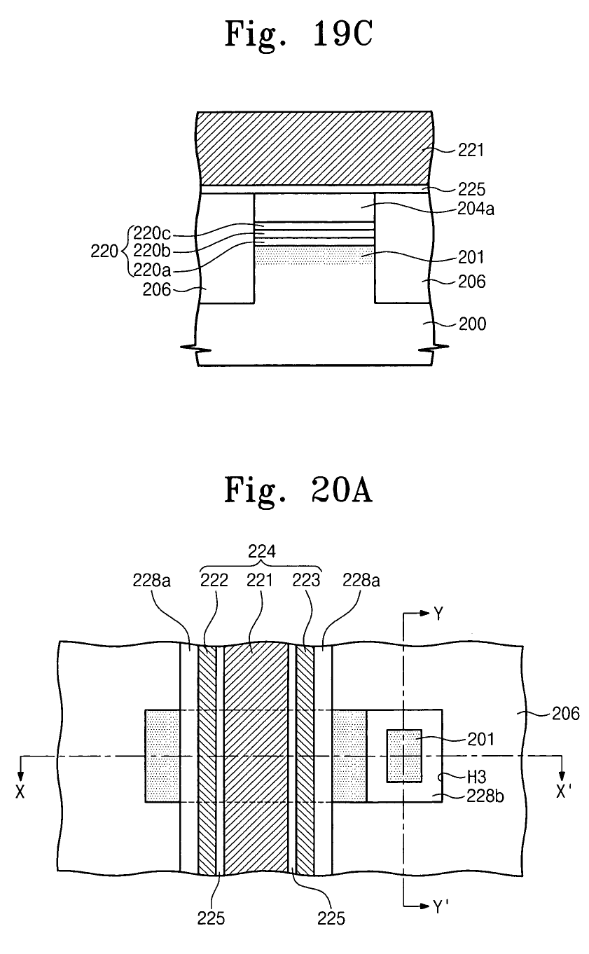

Referring to FIGS. 19A-19C, by using the first, second, and third gate conductive patterns 221, 222, and 223 as an etch mask, the preliminary first and second charge storage layers 217 and 218 may be anisotropically etched until the upper semiconductor pattern 204a is exposed in order to form a first upper charge storage layer 217a and a second upper charge storage layer 218a, which may be spaced from each other. Unlike example embodiments illustrated in FIG. 1, because the first, second, and third gate conductive patterns 221, 222, and 223 are used as an etch mask, the first and second upper charge storage layers 217a and 218a may substantially have the same length. Accordingly, a difference of a threshold voltage shift may become smaller, such that reliability of a non-volatile memory device may be improved.

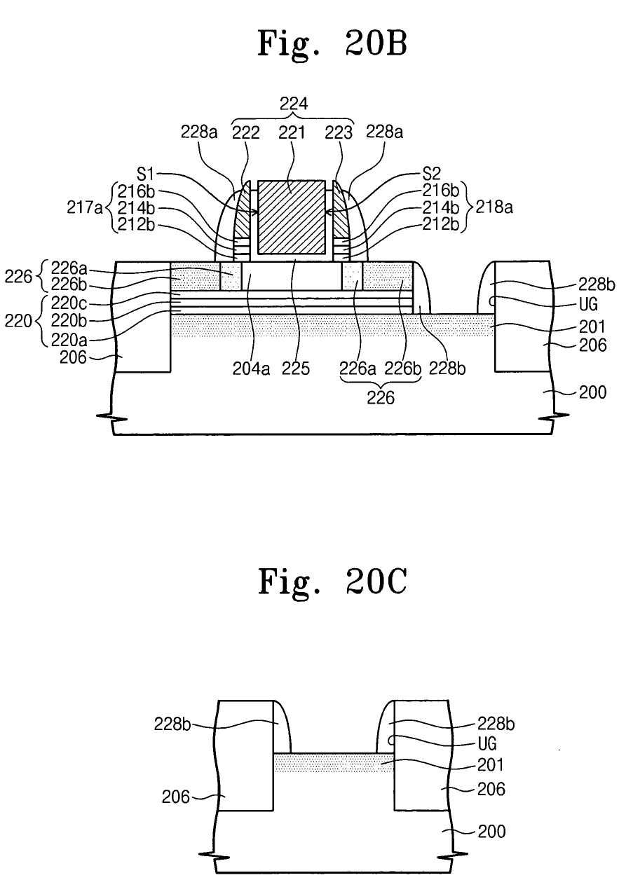

Each of the first and second upper charge storage layers 217a and 218a may include an anisotropically etched upper blocking pattern 216b, upper charge trap pattern 214b, and upper tunnel insulation pattern 212b. The gate insulation layer 225 may be disposed between the upper semiconductor pattern 204a and the first gate conductive pattern 221, between the first sidewall S1 (as shown in FIG. 20B) of the first gate conductive pattern 221 and the second gate conductive pattern 222, and between the second sidewall S2 (as shown in FIG. 20B) of the first gate conductive pattern 221 facing the first sidewall and the third gate conductive pattern 223. An ion implantation process may be performed on the upper semiconductor pattern 204a on both sides of the gate conductive structure 224 in order to form a low concentration impurity region 226a. The impurity may be an N-type.

Referring to FIGS. 20A through 20C, a lower gate groove UG may be formed to expose the lower high concentration impurity region 201 on the upper portion of the lower semiconductor substrate 200 and on the side of the semiconductor pattern 204a spaced apart from the gate conductive structure 224. The lower gate groove UG may be formed adjacent to the device isolation pattern 206. A spacer layer (not shown) may be conformally formed on the exposed lower high concentration impurity region 201 and the gate conductive structure 224. The spacer layer may have an etch selectivity with respect to the gate insulation layer 225.

For example, the spacer layer may be a silicon nitride layer or a silicon oxide nitride layer (SiON). The spacer layer may be anisotropically etched until the first, second, and third gate conductive patterns 221, 222, and 223 and the lower high concentration impurity region 201 in order to form a first spacer 228a on the outer sidewalls of the second gate conductive pattern 222 and the third gate conductive pattern 223 and a second spacer 228b on an inner wall of the lower gate groove UG. The second spacer 228b may prevent or reduce electrical contact between a source/drain region and a lower gate contact, which will be formed later.

An ion implantation process may be performed on the top surface of the semiconductor pattern 204a on both sides of the gate conductive structure 224 including the first spacer 228a, in order to form a high concentration impurity region 226b. The impurity may be an N-type. The low concentration impurity region 226a and the high concentration impurity region 226b may constitute a source/drain region 226.

The gate insulation layer 225 may be partially recessed between the first sidewall S1 of the first gate conductive pattern 221 and the second gate conductive pattern 222 and between the second sidewall S2 of the first gate conductive pattern 221 facing the first sidewall and the third gate conductive pattern 223. Accordingly, an upper portion of the first gate conductive pattern 221, an upper portion of the second gate conductive pattern 222, and an upper portion of the third gate conductive pattern 223 may protrude above the recessed surface of the gate insulation layer 225.

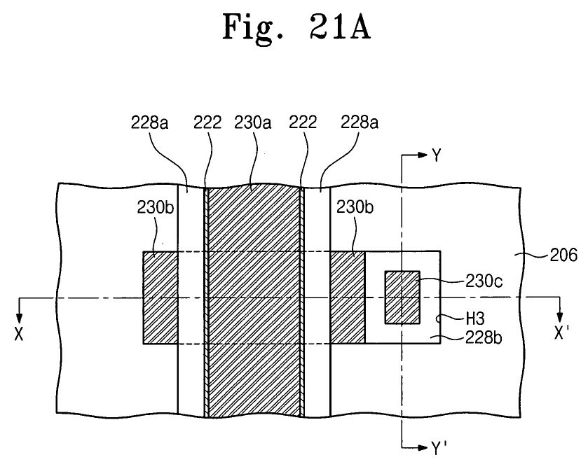

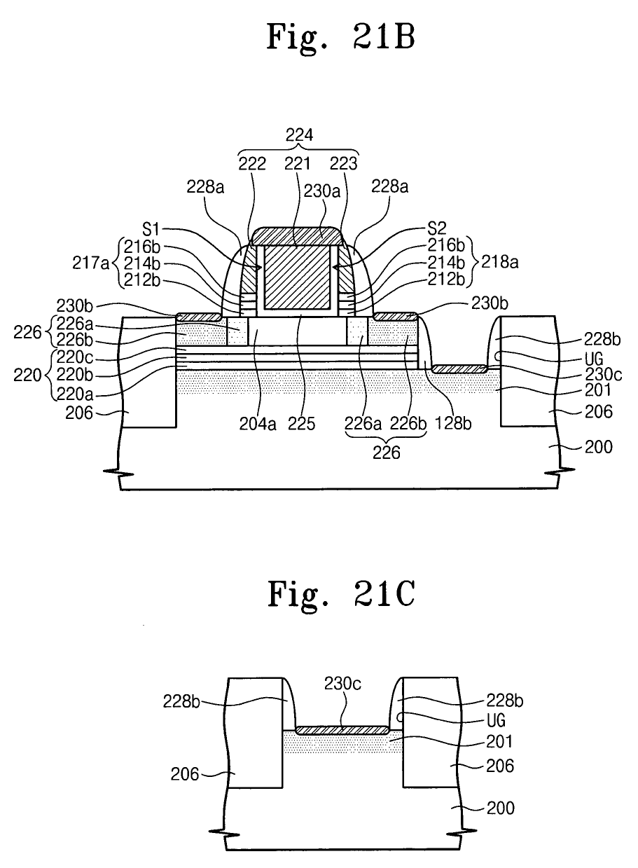

Referring to FIGS. 21A-21C, a connection part 230a may be formed on an upper portion of the first gate conductive pattern 221, an upper portion of the second gate conductive pattern 222, and an upper portion of the third gate conductive pattern 223. For example, if the first, second, and third gate conductive patterns are formed of polysilicon, a metal silicide layer as the connection parts 230a may be formed on the upper portion of the first gate conductive pattern 221, the upper portion of the second gate conductive pattern 222, and the upper portion of the third gate conductive pattern 223. When the metal silicide layer may be formed as the connection part 230a, metal silicide layers 230b and 230c may be simultaneously formed on the top surface of the source/drain region 226 and top surface of the lower high concentration impurity region 201 that is exposed by the lower gate groove UG.

Referring to FIG. 11, the interlayer insulation layer 240 may be formed to cover the gate conductive structure 224 and the exposed lower high concentration impurity region 201. The lower gate contact hole 242 may be formed to expose the lower high concentration impurity region 201 through the interlayer insulation layer 240. The conductive layer may be formed to fill the lower gate contact hole 242, such that the lower gate contact 244 may be formed. Contacts (not shown) may be formed to be electrically connected to the gate conductive structure 224 and the source/drain region 226 through the interlayer insulation layer 240.

As described above, according to example embodiments, a one cell-four bit non-volatile memory device may be realized, and overlap and disturb phenomena may be suppressed. Operational efficiency and reliability of a memory device having a one cell-four bit structure may be improved. According to example embodiments, a difference of a threshold voltage shift may become smaller, such that reliability of a non-volatile memory device may be improved also.

The above-disclosed subject matter is to be considered illustrative, and not restrictive, and the appended claims are intended to cover all such modifications, enhancements, and other embodiments, which fall within the true spirit and scope of example embodiments. Thus, to the maximum extent allowed by law, the scope of example embodiments may be determined by the broadest permissible interpretation of the following claims and their equivalents, and shall not be restricted or limited by the foregoing detailed description.

What is claimed is:

1. A non-volatile memory device comprising:
a lower semiconductor substrate;
an upper semiconductor pattern on the lower semiconductor substrate;
a device isolation pattern defining an active region in the lower semiconductor substrate and the upper semiconductor pattern;
a lower charge storage layer between the upper semiconductor pattern and the lower semiconductor substrate;
a gate conductive structure crossing over the upper semiconductor pattern;
a first upper charge storage layer and a second upper charge storage layer spaced apart from each other between the gate conductive structure and the upper semiconductor pattern; and
a source/drain region in the upper semiconductor pattern on both sides of the gate conductive structure.

2. The non-volatile memory device of claim 1, wherein the gate conductive structure includes a gate conductive pattern on the first and second upper charge storage layers and the upper semiconductor pattern between the spaced apart first and second upper charge storage layers, and further comprising:
a gate insulation layer between the first and second upper charge storage layers and between the gate conductive pattern and the upper semiconductor pattern.

3. The non-volatile memory device of claim 2, wherein each of the first and second upper charge storage layers includes an upper tunnel insulation pattern on the upper semiconductor pattern, an upper charge trap pattern on the upper tunnel insulation pattern, and an upper blocking insulation pattern on the upper charge trap pattern.

4. The non-volatile memory device of claim 1, wherein the gate conductive structure includes a first gate conductive pattern between the first upper charge storage layer and the second upper charge storage layer, a second gate conductive pattern adjacent to a first sidewall of the first gate conductive pattern, and a third gate conductive pattern adjacent to a second sidewall of the first gate conductive pattern facing the first sidewall, and further comprising:
a gate insulation layer between the upper semiconductor pattern and the first gate conductive pattern, between the first sidewall and the second conductive pattern, and between the second sidewall and the third gate conductive pattern.

5. The non-volatile memory device of claim 4, wherein the first upper charge storage layer is between the second gate conductive pattern and the upper semiconductor pattern, and the second upper charge storage layer is between the third gate conductive pattern and the upper semiconductor pattern.

6. The non-volatile memory device of claim 5, wherein each of the first and second upper charge storage layers includes an upper tunnel insulation pattern on the upper semiconductor pattern, an upper charge trap pattern on the upper tunnel insulation pattern, and an upper blocking insulation pattern on the upper charge trap pattern.

7. The non-volatile memory device of claim 4, wherein the gate conductive structure further comprises a connection part to electrically connect the first, second, and third gate conductive patterns, the connection part on an upper portion of the first gate conductive pattern, an upper portion of the second gate conductive pattern, and an upper portion of the third gate conductive pattern.

8. The non-volatile memory device of claim 7, wherein the connection part includes a metalized material.

9. The non-volatile memory device of claim 1, wherein the lower charge storage layer includes a lower blocking layer on the lower semiconductor substrate, a lower tunnel insulation layer contacting the upper semiconductor pattern on the lower blocking layer, and a lower charge trap layer between the lower blocking layer and the lower tunnel insulation layer.

10. The non-volatile memory device of claim 1, further comprising:
a lower high concentration impurity region in an upper portion of the lower semiconductor substrate; and
a lower gate contact spaced apart from the gate conductive structure and electrically connected to the lower high concentration impurity region through the upper semiconductor pattern and the lower charge storage layer,
wherein the upper semiconductor pattern and the lower charge storage layer include a lower gate groove to expose the lower high concentration impurity region.

11. The non-volatile memory device of claim 10, further comprising:
a first spacer on both sidewalls of the gate conductive structure and a second spacer on an inner wall of the lower gate groove.

12. A method of fabricating a non-volatile memory device, the method comprising:
providing a lower semiconductor substrate;
forming an upper semiconductor pattern on the lower semiconductor substrate;
forming a device isolation pattern to define an active region in the lower semiconductor substrate and the upper semiconductor pattern;
forming a lower charge storage layer between the upper semiconductor pattern and the lower semiconductor substrate;
forming a gate conductive structure to cross over the upper semiconductor pattern;
forming a first upper charge storage layer and a second upper charge storage layer spaced apart from each other between the gate conductive structure and the upper semiconductor pattern; and
forming a source/drain region in the upper semiconductor pattern on both sides of the gate conductive structure.

13. The method of claim 12, wherein forming the upper semiconductor pattern comprises:
forming a sacrificial layer on a preliminary lower semiconductor substrate; and
forming an upper semiconductor layer on the sacrificial layer.

14. The method of claim 13, wherein the sacrificial layer has an etch selectivity with respect to the upper semiconductor layer and the preliminary lower semiconductor substrate.

15. The method of claim 14, wherein forming the sacrificial layer includes forming a silicon germanium layer by performing an epitaxial growth process.

16. The method of claim 13, wherein forming the upper semiconductor layer includes forming a silicon layer by performing an epitaxial growth process.

17. The method of claim 12, wherein forming the device isolation pattern comprises:
patterning the upper semiconductor layer, the sacrificial layer, and the preliminary lower semiconductor substrate to form a upper semiconductor pattern, a sacrificial pattern, and a lower semiconductor substrate having a device isolation trench; and
forming a device isolation insulation layer to fill the device isolation trench.

18. The method of claim 17, wherein the device isolation insulation layer has an etch selectivity with respect to the upper semiconductor layer and the sacrificial layer.

19. The method of claim 17, wherein forming the lower charge storage layer comprises:
removing the sacrificial pattern to expose a bottom surface of the upper semiconductor pattern and a top surface of the lower semiconductor substrate;
forming a lower tunnel insulation layer on the bottom surface of the upper semiconductor pattern and a lower blocking layer on the top surface of the lower semiconductor substrate; and
forming a lower charge trap layer between the lower tunnel insulation layer and the lower blocking layer.

20. The method of claim 19, wherein removing the sacrificial pattern comprises:
partially exposing the device isolation insulation layer contacting the upper semiconductor pattern;
recessing the exposed device isolation insulation layer to expose a side of the sacrificial pattern; and
selectively performing an isotropic etching process on the exposed sacrificial pattern.

21. The method of claim 20, wherein partially exposing the device isolation insulation layer comprises:
forming a first mask layer on the upper semiconductor pattern and the device isolation insulation layer; and
patterning the first mask layer to form a first mask pattern having a first groove, the first groove exposing the upper semiconductor pattern and the device isolation insulation layer that contacts the upper semiconductor pattern.

22. The method of claim 21, wherein the first mask layer has an etch selectivity with respect to the upper semiconductor pattern, the sacrificial pattern, and the device isolation insulation layer.

23. The method of claim 21, wherein recessing the exposed device isolation insulation layer includes etching the device isolation insulation layer, exposed through the first groove, to form a second groove, the second groove extending from the first groove partially.

24. The method of claim 19, wherein forming the lower tunnel insulation layer and the lower blocking layer includes forming a silicon oxide layer by performing a chemical vapor deposition (CVD) process.

25. The method of claim 19, wherein forming the lower charge trap layer includes forming a silicon nitride layer by performing a CVD process.

26. The method of claim 12, wherein forming the first and second upper charge storage layers comprises:
forming an upper tunnel insulation layer on the upper semiconductor pattern, an upper charge trap layer on the upper tunnel insulation layer, and an upper blocking layer on the upper charge trap layer; and
patterning the upper blocking layer, the upper charge trap layer, and the upper tunnel insulation layer to form a preliminary first upper charge storage layer and a preliminary second upper charge storage layer, which are spaced apart from each other,
wherein each of the preliminary first and second upper charge storage layers includes a preliminary upper blocking pattern, a preliminary upper charge trap pattern, and a preliminary upper tunnel insulation pattern.

27. The method of claim 26, wherein forming the gate insulation layer and the gate conductive structure comprises:
forming a gate insulation layer on the exposed upper semiconductor layer; and
forming a gate conductive layer to cover the gate insulation layer, the preliminary first upper charge storage layer, and the preliminary second upper charge storage layer.

28. The method of claim 12, wherein forming the first and second upper charge storage layers comprises:
forming an upper tunnel insulation layer on the upper semiconductor pattern, an upper charge trap layer on the upper tunnel insulation layer, and an upper blocking layer on the upper charge trap layer;
forming a second mask pattern on the upper blocking layer; and
etching the upper blocking layer, the upper charge trap layer, and the upper tunnel insulation layer by using the second mask pattern as an etch mask to form a trench and preliminary first and second upper charge storage layers, the trench exposing the upper semiconductor pattern and being between the preliminary first and second upper charge storage layers, the preliminary first and second upper charge storage layers being spaced apart from each other,
wherein each of the preliminary first and second upper charge storage layers includes a preliminary upper blocking pattern, a preliminary upper charge trap pattern, and a preliminary upper tunnel insulation pattern.

29. The method of claim 28, wherein forming the gate insulation layer and the gate conductive structure comprises:
forming a gate insulation layer on the exposed upper semiconductor substrate and on an inner wall of the trench;
forming a first gate conductive layer to fill the trench having the gate insulation layer in order to form a first gate conductive pattern;
removing the second mask pattern to expose the preliminary upper blocking pattern;
conformally forming a second gate conductive layer on the upper semiconductor pattern including the exposed preliminary upper blocking pattern; and
performing an anisotropic etching process on the second gate conductive layer until the first gate conductive pattern is exposed, in order to form a second gate conductive pattern and a third gate conductive pattern.

30. The method of claim 29, wherein the second mask pattern has an etch selectivity with respect to the gate insulation layer and the blocking layer.

31. The method of claim 28, wherein forming the first and second upper charge storage layers further comprises:
performing an anisotropic etching process on the preliminary first and second upper charge storage layers by using the first, second, and third gate conductive patterns as an etch mask until the upper semiconductor pattern is exposed.

32. The method of claim 31, wherein forming the gate conductive structure further comprises:
forming a first spacer at an outer sidewall of the second gate conductive pattern and an outer sidewall of the third gate conductive pattern;
recessing the gate insulation layer; and
forming a connection part on an upper portion of the first gate conductive pattern, an upper portion of the second gate conductive pattern, and an upper portion of the third gate conductive pattern.

33. The method of claim 32, wherein the connection part includes a metalized material.

34. The method of claim 12, further comprising:
forming a lower high concentration impurity region on an upper portion of the lower semiconductor substrate;
forming a lower gate groove spaced apart from the gate conductive structure and exposing the lower high concentration impurity region through the upper semiconductor pattern and the lower charge storage layer;
forming an interlayer insulation layer to cover the exposed lower high concentration impurity region; and
forming a lower gate contact to be electrically connected to the lower high concentration impurity region through the interlayer insulation layer.

35. The method of claim 34, further comprising:
forming a second spacer on an inner wall of the lower gate groove.
